(19) United States
(12) Patent Application Publication
(10) Pub. No.: US 2025/0143091 A1
(43) Pub. Date: May 1, 2025

(54) DISPLAY DEVICE

(71) Applicant: Samsung Display Co., Ltd., Yongin-Si (KR)

(72) Inventors: Hyun Eok SHIN, Yongin-si (KR); Byung Soo SO, Yongin-si (KR); Ju Hyun LEE, Yongin-si (KR); Yung Bin CHUNG, Yongin-si (KR); Yu Gwang JEONG, Yongin-si (KR)

(21) Appl. No.: 18/758,082

(22) Filed: Jun. 28, 2024

(30) Foreign Application Priority Data
Oct. 27, 2023 (KR) 10-2023-0145272

(51) Int. Cl. H10K 59/122

(52) U.S. Cl. CPC H10K 59/122

(57) ABSTRACT

A display device includes a first separation layer disposed in an emission area of a substrate, a second separation layer disposed on the first separation layer, an insulating layer disposed on the second layer, a first electrode disposed on the insulating layer, a light emitting structure disposed on the first electrode, and a second electrode disposed on the light emitting structure. The first electrode includes a first area on the second layer and a second area electrically separated from the first area.

### CROSS-REFERENCE TO RELATED APPLICATION(S)

This application claims priority, under 35 U.S.C. § 119, to Korean Patent Application No. 10-2023-0145272 filed on Oct. 27, 2023 in the Korean Intellectual Property Office, the disclosure of which is incorporated herein by reference in its entirety herein.

### BACKGROUND

### 1. Field

The present disclosure generally relates to a display device.

### 2. Description of the Related Art

Recently, increasing interest in information displays has been fueling research and development of display devices.

### SUMMARY

Embodiments may provide an ultra high definition display device with improved reliability.

An embodiment of a display device includes: a first separation layer disposed in an emission area of a substrate; a second layer disposed on the first separation layer; an insulating layer disposed on the second separation layer; a first electrode disposed on the insulating layer; a light emitting structure disposed on the first electrode; and a second electrode disposed on the light emitting structure, wherein the first electrode includes a first area on the second separation layer and a second area electrically separated from the first area.

A width of the second separation layer in a first direction may be greater than a width of the first separation layer in the first direction.

A width by which the second separation layer extends beyond the first separation layer may be greater than a thickness of the first electrode.

At least part of the light emitting structure may be discontinuous on the second area of the first electrode.

The first electrode may include a first electrode layer disposed on the insulating layer and a second electrode layer disposed on the first electrode layer.

The first electrode may further include a third electrode layer disposed on the second electrode layer.

The first electrode layer and the third electrode layer may include the same material.

A thickness of the first separation layer may be greater than a sum of a thickness of the insulating layer and a thickness of the first electrode.

The insulating layer may cover the first separation layer and the second separation layer.

The first area of the first electrode may be electrically connected to the second separation layer through a contact hole that extends through the insulating layer.

The substrate may include a first sub-pixel and a second sub-pixel that are adjacently positioned. The second area of the first electrode may be disposed in a boundary area between the first sub-pixel and the second sub-pixel.

The light emitting structure of the first sub-pixel and the light emitting structure of the second sub-pixel may be separated from each other on the second area of the first electrode.

The second electrode of the first sub-pixel and the second electrode of the second sub-pixel may be connected to each other on the second area of the first electrode.

The first separation layer and the second separation layer may include a conductive material.

An embodiment of a display device includes: a first separation layer disposed in an emission area of a substrate; a second separation layer disposed on the first separation layer; an anode electrode disposed on the second separation layer; a conductive pattern disposed in the same layer as the first separation layer, the conductive pattern being electrically separated from the anode electrode; a light emitting structure disposed on the anode electrode and the conductive pattern; and a cathode electrode disposed on the light emitting structure, wherein the anode electrode and the conductive pattern include the same material.

The display device may further include a circuit layer disposed between the substrate and the anode electrode.

The second separation layer may be electrically connected to the circuit layer through a contact hole that extends through the first separation layer.

The anode electrode may be electrically connected to the circuit layer through a contact hole that extends through the second separation layer and the first separation layer.

The first separation layer may include an insulating material, and the second separation layer may include a conductive material.

The first separation layer and the second separation layer may include an insulating material.

### BRIEF DESCRIPTION OF THE DRAWINGS

The above and other features of embodiments of the present disclosure will become more apparent by describing in further detail non-limiting embodiments thereof with reference to the accompanying drawings, in which:

FIG. 1 is a block diagram illustrating an embodiment of a display device.

FIG. 2 is a block diagram illustrating an embodiment of any one of sub-pixels shown in FIG. 1.

FIG. 3 is a circuit diagram illustrating an embodiment of the sub-pixel shown in FIG. 2.

FIG. 4 is a plan view illustrating an embodiment of a display panel shown in FIG. 1.

FIG. 5 is an exploded perspective view illustrating a portion of the display panel shown in FIG. 4.

FIG. 6 is a plan view illustrating an embodiment of any one of pixels shown in FIG. 5.

FIG. 7 is a cross-sectional view illustrating an embodiment taken along line I-I′ shown in FIG. 6.

FIG. 8 is a cross-sectional view illustrating an embodiment of an anode electrode shown in FIG. 7.

FIG. 9 is a cross-sectional view illustrating an embodiment of the anode electrode shown in FIG. 7.

FIG. 10 is a cross-sectional view illustrating an embodiment taken along the line I-I′ shown in FIG. 6.

FIG. 11 is a cross-sectional view illustrating an embodiment taken along the line I-I′ shown in FIG. 6.

FIG. 12 is a cross-sectional view illustrating an embodiment of a light emitting structure included in any one of first to third light emitting elements shown in FIG. 7.

FIG. 13 is a cross-sectional view illustrating an embodiment of the light emitting structure included in the one of the first to third light emitting elements shown in FIG. 7.

FIG. 14 is a plan view illustrating an embodiment of the one of the pixels shown in FIG. 5.

FIG. 15 is a plan view illustrating an embodiment of the one of the pixels shown in FIG. 5.

FIG. 16 is a block diagram illustrating an embodiment of a display system.

FIG. 17 is a perspective view illustrating an application example of the display system shown in FIG. 16.

FIG. 18 is a view illustrating a head-mounted display device shown in FIG. 17, which is worn by a user.

FIGS. 19, 20, 21, 22, 23, 24, 25, and 26 are cross-sectional views illustrating process stages of manufacturing a display device in accordance with an embodiment of the present disclosure.

### DETAILED DESCRIPTION

Hereinafter, an embodiment according to the disclosure is described in more detail with reference to the accompanying drawings. It should be noted that in the following description, only portions necessary for understanding an operation according to the disclosure are described, and descriptions of other portions are omitted in order not to obscure the subject matter of the disclosure. In some embodiments, the disclosure may be embodied in other forms without being limited to the embodiment described herein. However, the embodiment described herein is provided to describe in more detail enough to easily implement the technical spirit of the disclosure to those skilled in the art to which the disclosure belongs.

Throughout the specification, in a case where a portion is “connected” to another portion, the case includes not only a case where the portion is “directly connected” but also a case where the portion is “indirectly connected” with another element interposed therebetween. Like reference numerals refer to like elements throughout, and duplicative descriptions may be omitted. In some embodiments, in the drawings, the thicknesses, ratios, and dimensions of elements are exaggerated for effective description of the technical contents. As utilized herein, the term “and/or” includes any and all combinations that the associated configurations can define.

Terms utilized herein are for describing specific embodiments and are not intended to limit the disclosure. Throughout the specification, in a case where a certain portion “includes”, the case refers to that the portion may further include another component without excluding another component unless otherwise stated. “At least any one of X, Y, and Z” and “at least any one selected from a group consisting of X, Y, and Z” may be interpreted as one X, one Y, one Z, or any combination of two or more of X, Y, and Z (for example, XYZ, XYY, YZ, and ZZ). Here, “and/or” includes all combinations of one or more of corresponding configurations. The terms of a singular form include plural forms unless otherwise specified. For example, “a,” “an,” and “the” are intended to include the plural forms as well, unless the context clearly indicates otherwise.

As utilized herein, the terms “use,” “using,” and “used” may be considered synonymous with the terms “utilize,” “utilizing,” and “utilized,” respectively.

As utilized herein, expressions such as “at least one of,” “one of,” “selected from,” and “selected from among,” when preceding a list of elements, modify the entire list of elements and do not modify the individual elements of the list. For example, the expressions “at least one of a to c,” “at least one of a, b or c,” and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

The term “and/or” includes all combinations of one or more of the associated listed elements.

In the present application, when a layer, a film, a region, or a plate is referred to as being “on” or “in an upper portion of” another layer, film, region, or plate, it may or may not be “directly on” the layer, film, region, or plate, and intervening layers, films, regions, or plates may be present. Similarly, when a layer, a film, a region, or a plate is referred to as being “in a lower portion of” another layer, film, region, or plate, it may or may not be directly under the layer, film, region, or plate, and intervening layers, films, regions, or plates may be present. In some embodiments, it will be understood that when a part is referred to as being “on” another part, it can be provided above the other part, or provided under the other part as well. It will be understood that the terms “include” “includes,” “including,” “comprise,” “comprises”, “comprising,” “has,” “having,” and/or “have”, when utilized in this specification, specify the presence of stated features, integers, steps, operations, elements, components and/or groups thereof, but do not preclude the presence or addition of one or more other features, integers, steps, operations, elements, components, and/or groups thereof.

As utilized herein, the term “may” will be understood to refer to “one or more embodiments of the present disclosure,” some of which include the described element and some of which exclude that element and/or include an alternate element. Similarly, alternative language such as “or” refers to “one or more embodiments of the present disclosure,” each including a corresponding listed item.

Unless otherwise defined, all terms (including chemical, technical and scientific terms) utilized herein have the same meaning as commonly understood by one of ordinary skill in the art to which this present disclosure belongs. It will be further understood that terms, such as those defined in commonly utilized dictionaries, should be interpreted as having a meaning that is consistent with their meaning in the context of the relevant art and will not be interpreted in an idealized or overly formal sense unless expressly so defined herein.

As utilized herein, the phrase “consisting essentially of” means that any additional components will not materially affect the chemical, physical, optical, or electrical properties of the semiconductor film.

As utilized herein, the phrase “on a plane,” or “plan view,” refers to viewing a target portion from the top, and the phrase “on a cross-section” means viewing a cross-section formed by vertically cutting a target portion from the side.

In present disclosure, “not include a or any ‘component’” “exclude a or any ‘component’”, “‘component’-free”, and/or the like refers to that the “component” not being added, selected or utilized as a component in the composition, but the “component” of less than a suitable amount may still be included due to other impurities and/or external factor.

Here, terms such as first and second may be utilized to describe one or more suitable components, but these components are not limited to these terms. These terms are utilized to distinguish one component from another component. Therefore, a first component may refer to a second component within a range without departing from the scope disclosed herein.

Spatially relative terms such as “under”, “on”, and/or the like may be utilized for descriptive purposes, thereby describing a relationship between one element or feature and another element(s) or feature(s) as shown in the drawings. Spatially relative terms are intended to include other directions in utilize, in operation, and/or in manufacturing, in addition to the direction depicted in the drawings. For example, if (e.g., when) a device shown in the drawing is turned upside down, elements depicted as being positioned “under” other elements or features are positioned in a direction “on” the other elements or features. Therefore, in some embodiments, the term “under” may include both (e.g., simultaneously) directions of on and under. In some embodiments, the device may face in other directions (for example, rotated 90 degrees or in other directions) and thus the spatially relative terms utilized herein are interpreted according thereto.

Various embodiments are described with reference to drawings schematically illustrating ideal embodiments. Accordingly, it will be expected that shapes may vary, for example, according to tolerances and/or manufacturing techniques. Therefore, the embodiments disclosed herein cannot be construed as being limited to specific shapes, and should be interpreted as including, for example, changes in shapes that occur as a result of manufacturing. As described herein, the shapes shown in the drawings may not be the actual shapes of areas of a device, and the present embodiments are not limited thereto.

Hereinafter, embodiments of the disclosure will be described in more detail with reference to the accompanying drawings.

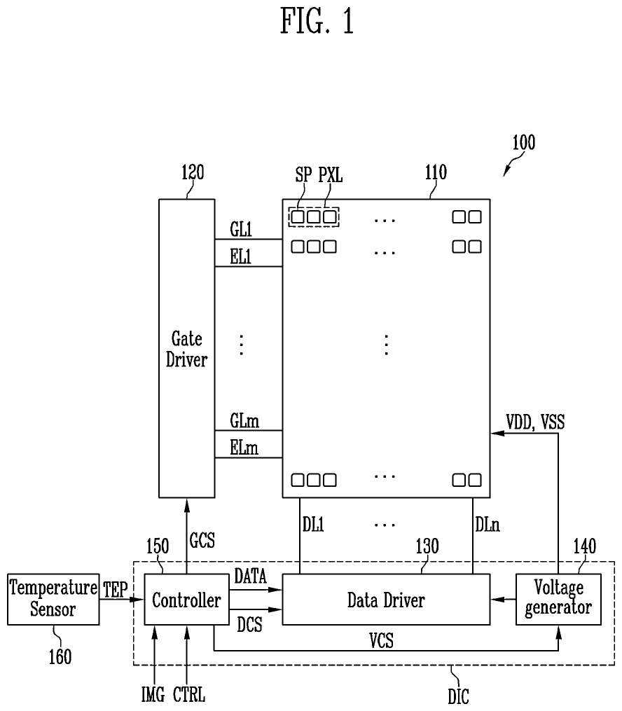

FIG. 1 is a block diagram illustrating an embodiment of a display device.

Referring to FIG. 1, the display device 100 may include a display panel 110, a gate driver 120, a data driver 130, a voltage generator 140, and a controller 150.

The display panel 110 may include sub-pixels SP. The sub-pixels SP may be connected to the gate driver 120 through first to mth gate lines GL1 to GLm. The sub-pixels SP may be connected to the data driver 130 through first to nth data lines DL1 to DLn.

Each of the sub-pixels SP may include at least one light emitting element configured to generate light. Accordingly, each of the sub-pixels SP may generate light of a specific color such as red, green, blue, cyan, magenta or yellow. Two or more sub-pixels among the sub-pixels SP may constitute one pixel PXL. For example, three sub-pixels SP may constitute one pixel PXL as shown in FIG. 1.

The gate driver 120 may be connected to the sub-pixels SP arranged in a row direction through the first to mth gate lines GL1 to GLm. The gate driver 120 may output gate signals to the first to mth gate lines GL1 to GLm in response to a gate control signal GCS. In some embodiments, the gate control signal GCS may include a start signal indicating a start of each frame, a horizontal synchronization signal for outputting gate signals in synchronization with timings at which data signals are applied, and the like.

In some embodiments, first to mth light emitting control lines EL1 to ELm connected to the sub-pixels SP in the row direction may be further provided. The gate driver 120 may include an emission control driver configured to control the first to mth emission control lines EL1 to ELm, and the emission control driver may operate under the control of the controller 150.

The gate driver 120 may be disposed at one side of the display panel 110. However, embodiments of the present disclosure are not limited thereto. For example, the gate driver 120 may be divided into two or more drivers which are physically and/or logically divided, and these drivers may be disposed at one side of the display panel 110 and the other side of the display panel 110, which is opposite to the one side. As such, in some embodiments, the gate driver 120 may be disposed in various forms at the periphery of the display panel 110.

The data driver 130 may be connected to the sub-pixels SP arranged in a column direction through the first to nth data lines DL1 to DLn. The data driver 130 may receive image data DATA and a data control signal DCS from the controller 150. The data driver 130 may operate in response to the data control signal DCS. In some embodiments, the data control signal DCS may include a source start pulse, a source shift clock, a source output enable signal, and the like.

The data driver 130 may apply data signals having grayscale voltages corresponding to the image data DATA to the first to nth data lines DL1 to DLn by using voltages from the voltage generator 140. When a gate signal is applied to each of the first to mth gate lines GL1 to GLm, data signals corresponding to the image data DATA may be applied to the data line DL1 to DLm. Accordingly, corresponding sub-pixels SP may generate light corresponding to the data signals. Accordingly, an image may be displayed on the display panel 110.

In some embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 may be configured to generate a plurality of voltages and provide the generated voltages to components of the display device 100. For example, the voltage generator 140 may be configured to generate a plurality of voltages by receiving an input voltage from the outside of the display device 100, adjusting the received voltage, and regulating the adjusted voltage.

The voltage generator 140 may generate a first power voltage VDD and a second power voltage VSS, and the generated first and second power voltages VDD and VSS may be provided to the sub-pixels SP. The first power voltage VDD may have a relatively high voltage level, and the second power voltage VSS may have a voltage level lower than the voltage level of the first power voltage VDD. In other embodiments, the first power voltage VDD or the second power voltage VSS may be provided by an external device of the display device 100.

Besides, the voltage generator 140 may generate various voltages. For example, the voltage generator 140 may generate an initialization voltage applied to the sub-pixels SP. For example, a predetermined reference voltage may be applied to the first to nth data lines DL1 to DLn in a sensing operation for sensing electrical characteristics of transistors and/or light emitting elements of the sub-pixels SP, and the voltage generator 140 may generate the reference voltage.

The controller 150 may control overall operations of the display device 100. The controller 150 may receive, from the outside, input image data IMG and a control signal CTRL for controlling display thereof. The controller 150 may provide the gate control signal GCS, the data control signal DCS, and the voltage control signal VCS in response to the control signal CTRL.

The controller 150 may convert the input image data IMG to be suitable for the display device 100 or the display panel 110, thereby outputting the image data DATA. In some embodiments, the controller 150 may align the input image data IMG to be suitable for the sub-pixels SP in units of rows, thereby outputting the image data DATA.

Two or more components of the data driver 130, the voltage generator 140, and the controller 150 may be mounted on one integrated circuit. As shown in FIG. 1, the data driver 130, the voltage generator 140, and the controller 150 may be included in a driver integrated circuit DIC. The data driver 130, the voltage generator 140, and the controller 150 may be components functionally divided in one driver integrated circuit DIC. In other embodiments, at least one of the data driver 130, the voltage generator 140, and the controller 150 may be provided as a component distinguished from the driver integrated circuit DIC.

The display device 100 may include at least one temperature sensor 160. The temperature sensor 160 may be configured to sense a temperature at the periphery thereof and generate temperature data TEP indicating the sensed temperature. some embodiments, the temperature sensor 160 may be disposed to be adjacent to the display panel 110 and/or the driver integrated circuit DIC.

The controller 150 may control various operations of the display device 100 in response to the temperature data TEP. In some embodiments, the controller 150 may adjust the luminance of an image output from the display panel 100 in response to the temperature data TEP. For example, the controller 150 may control components such as the data driver 130 and/or the voltage generator 140, thereby adjusting data signals and the first and second power voltages VDD and VSS.

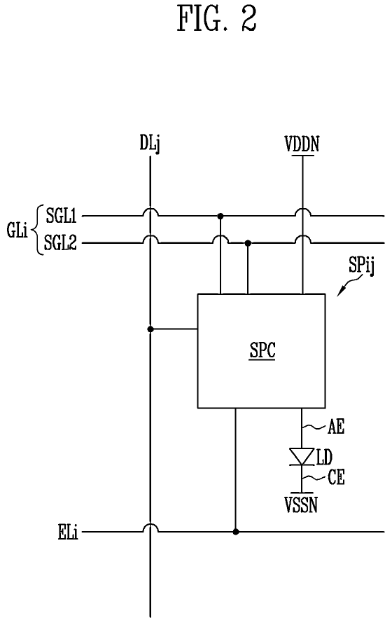

FIG. 2 is a block diagram illustrating an embodiment of any one of sub-pixels shown in FIG. 1. In FIG. 2, a sub-pixel SPij arranged on an ith row (i is an integer which is greater than or equal to 1 and is smaller than or equal to m) and a jth column (j is an integer which is greater than or equal to 1 and is smaller than or equal to n) among the sub-pixels SP shown in FIG. 1 may be exemplarily illustrated.

Referring to FIG. 2, the sub-pixel Spij may include a sub-pixel circuit SPC and a light emitting element LD.

The light emitting element LD may be connected between a first power voltage node VDDN and a second power voltage node VSSN. The first power voltage node VDDN may be a node transferring the first power voltage VDD shown in FIG. 1, and the second power voltage node VSSN may be a node transferring the second power voltage VSS shown in FIG. 1.

An anode electrode AE of the light emitting element LD may be connected to the first power voltage node VDDN through the sub-pixel circuit SPC, and a cathode electrode CE of the light emitting element LD may be connected to the second power voltage node VSSN. For example, the anode electrode AE of the light emitting element LD may be connected to the first power voltage node VDDN through one or more transistors included in the sub-pixel circuit SPC.

The sub-pixel circuit SPC may be connected to an ith gate line Gli among the first to mth gate lines GL1 to GLm shown in FIG. 1, an ith emission control line Eli among the first to mth emission control lines EL1 to Elm shown in FIG. 1, and a jth data line DLj among the first to nth data lines DL1 to DLn shown in FIG. 1. The sub-pixel circuit SPC may be configured to control the light emitting element LD according to signals received through these signal lines.

The sub-pixel circuit SPC may operate in response to a gate signal received through the ith gate line Gli. The ith gate line Gli may include one or more sub-gate lines. In some embodiments, as shown in FIG. 2, the ith gate line GLi may include first and second sub-gate lines SGL1 and SGL2. The sub-pixel circuit SPC may operate in response to gate signals received through the first and second sub-gate lines SGL1 and SGL2. As such, when the ith gate line GLi includes two or more sub-gate lines, the sub-pixel circuit SPC may operate in response to gate signals received through the corresponding sub-gate lines.

The sub-pixel circuit SPC may operate in response to an emission control signal received through the ith emission control line ELi. In some embodiments, the ith emission control line ELi may include one or more sub-emission control lines. When the ith emission control line ELi includes two or more sub-emission control lines, the sub-pixel circuit SPC may operate in response to emission control signals receives through the corresponding emission control lines.

The sub-pixel circuit SPC may receive a data signal through the jth data line DLj. The sub-pixel circuit SPC may store a voltage corresponding to the data signal in response to at least one of the gate signals received through the first and second sub-gate lines SGL1 and SGL2. The sub-pixel circuit SPC may control a current flowing from the first power voltage node VDDN to the second power voltage node VSSN through the light emitting element LD according to the stored voltage in response to the emission control signal received through the ith emission control line ELi. Accordingly, the light emitting element LD may generate light with a luminance corresponding to the data signal.

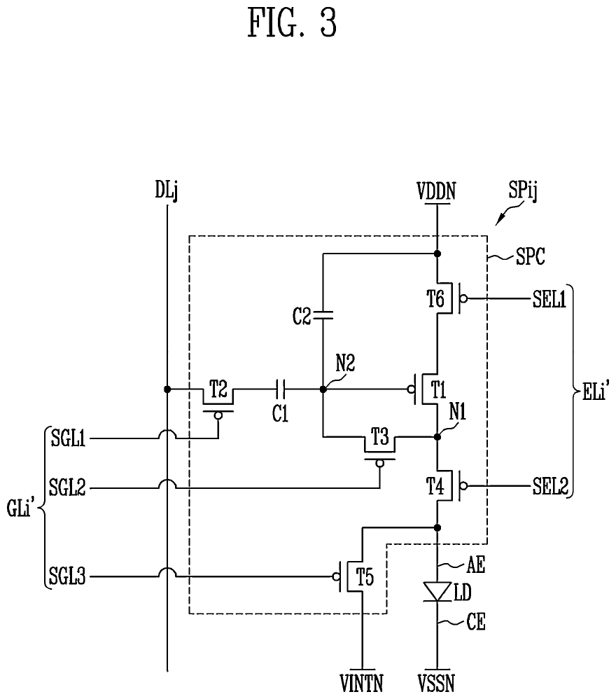

FIG. 3 is a circuit diagram illustrating an embodiment of the sub-pixel shown in FIG. 2.

Referring to FIG. 3, the sub-pixel SPij may include a sub-pixel circuit SPC and a light emitting element LD.

The sub-pixel circuit SPC may be connected to an ith gate line GLi′, an ith emission control line ELi′, and a jth data line DLj. When comparing the ith gate line GLi′ with the ith gate line GLi shown in FIG. 2, the ith gate line GLi′ may further include a third sub-gate line SGL3. When comparing the ith emission control line ELi′ with the ith emission control line ELi shown in FIG. 2, the ith emission control line ELi′ may include a first sub-emission control line SEL1 and a second sub-emission control line SEL2.

The sub-pixel circuit SPC may include first to sixth transistors T1 to T6 and first and second capacitors C1 and C2.

The first transistor T1 may be connected between a first power voltage node VDDN and a first node N1. A gate of the first transistor T1 may be connected to a second node N2, and accordingly, the first transistor T1 may be turned on according to a voltage level of the second node N2. The first transistor T1 may be designated as a driving transistor.

The second transistor T2 may be connected between the jth data line DLj and the second node N2. A gate of the second transistor T2 may be connected to a first sub-gate line SGL1, and accordingly, the second transistor T2 may be turned on in response to a gate signal of the first sub-gate line SGL1. The second transistor T2 may be designated as a switching transistor.

The third transistor T3 may be connected between the first node N1 and the second node N2. A gate of the third transistor T3 may be connected to a second sub-gate line SGL2, and accordingly, the third transistor T3 may be turned on in response to a gate signal of the second sub-gate line SGL2.

The fourth transistor T4 may be connected between the first node N1 and an anode electrode AE of the light emitting element LD. A gate of the fourth transistor T4 may be connected to the second sub-emission control line SEL2, and accordingly, the fourth transistor T4 may be turned on in response to an emission control signal of the second sub-emission control line SEL2.

The fifth transistor T5 may be connected between the anode electrode AE of the light emitting element LD and an initialization voltage node VINTN. The initialization voltage node VINTN may be configured to transfer an initialization voltage. In some embodiments, the initialization voltage may be provided by the voltage generator 140 shown in FIG. 1. In other embodiments, the initialization voltage may be provided by an external device of the display device 100. A gate of the fifth transistor T5 may be connected to the third sub-gate line SGL3, and accordingly, the fifth transistor T5 may be turned on in response to a gate signal of the third sub-gate line SGL3.

The sixth transistor T6 may be connected between the first power voltage node VDDN and the first transistor T1. A gate of the sixth transistor T6 may be connected to the first sub-emission control line SEL1, and accordingly, the sixth transistor T6 may be turned on in response to an emission control signal of the first sub-emission control line SEL1.

The first capacitor C1 may be connected between the second transistor T2 and the second node N2. The second capacitor C2 may be connected between the first power voltage node VDDN and the second node N2.

As such, the sub-pixel circuit SPC may include the first to sixth transistors T1 to T6 and the first and second capacitors C1 and C2. However, embodiments of the present disclosure are not limited thereto. The sub-pixel circuit SPC may be implemented as any one of various types of circuits each including a plurality of transistors and one or more capacitors. For example, the sub-pixel circuit SPC may include two transistors and one capacitor. In accordance with embodiments of the sub-pixel circuit SPC, the number of sub-gate lines included in the ith gate line GLi′ and the number of sub-emission control lines included in the ith emission control line ELi′ may vary.

The first to sixth transistors T1 to T6 may be P-type transistors. Each of the first to sixth transistors T1 to T6 may be a Metal Oxide Silicon Field Effect Transistor (MOSEFT). However, embodiments of the present disclosure are not limited thereto. For example, at least one of the first to sixth transistors T1 to T6 may be replaced with an N-type transistor.

In some embodiments, the first to sixth transistors T1 to T6 may include an amorphous silicon semiconductor, a monocrystalline silicon semiconductor, a polycrystalline silicon semiconductor, an oxide semiconductor, and the like.

The light emitting element LD may include the anode electrode AE, a cathode electrode CE, and a light emitting layer. The light emitting layer may be disposed between the anode electrode AE and the cathode electrode CE. After a data signal transferred through the jth data line DLj is reflected on a voltage of the second node N2, the fourth and sixth transistors T4 and T6 may be turned on when the emission control signals of the first and second sub-emission control lines SEL1 and SEL2 are enabled to a low level. The first transistor T1 may be turned on according to the voltage of the second node N2, and accordingly, a current may flow from the first power voltage node VDDN to a second power voltage node VSSN. The light emitting element LD may emit light according to an amount of the current flowing from the first power voltage node VDDN to the second power voltage node VSSN.

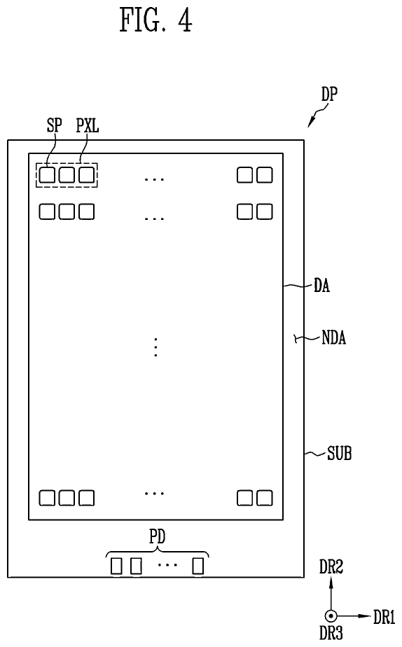

FIG. 4 is a plan view illustrating an embodiment of a display panel shown in FIG. 1.

Referring to FIG. 4, the embodiment DP of the display panel 110 shown in FIG. 1 may include a display area DA and a non-display area NDA. The display panel DP may display an image through the display area DA. The non-display area NDA may be disposed at the periphery of the display area DA.

The display panel DP may include a substrate SUB, sub-pixels SP, and pads PD.

When the display panel DP is used as a display screen of a Head Mounted Display (HMD), a Virtual Reality (VR) device, a Mixed Reality (MR) device, an Augmented Reality (AR) device, and the like, the display panel DP may be located very close to the eyes of a user. The sub-pixels SP having a relatively high degree of integration may be required. In order to increase the integration of the sub-pixels SP, the substrate SUB may be provided as a silicon substrate. The sub-pixels SP and/or the display panel DP may be formed on the substrate SUB as the silicon substrate. The display device 100 (see FIG. 1) including the display panel DP formed on the substrate SUB as the silicon substrate may be designated as an OLED on Silicon (OLEDoS) display device.

The sub-pixels SP may be disposed in the display area DA on the substrate SUB. The sub-pixels SP may be arranged in a matrix form along a first direction DR1 and a second direction DR2 intersecting the first direction DR1. However, embodiments of the present disclosure are not limited thereto. For example, the sub-pixels SP may be arranged in a zigzag form along the first direction DR1 and the second direction DR2. For example, the sub-pixels SP may be disposed in a PENTILE™ form. The first direction DR1 may be a row direction, and the second direction DR2 may be a column direction.

Two or more sub-pixels among the sub-pixels SP may constitute one pixel PXL.

A component for controlling the sub-pixels SP may be disposed in the non-display area NDA on the substrate SUB. For example, lines connected to the sub-pixels SP, such as the first to mth gate lines GL1 to GLm and the first to nth data lines DL1 to DLn, which are shown in FIG. 1, may be disposed in the non-display area NDA.

At least one of the gate driver 120, the data driver 130, the voltage generator 140, the controller 150, and the temperature sensor 160, which are shown in FIG. 1, may be integrated in the non-display area NDA of the display panel DP. In some embodiments, the gate driver 120 shown in FIG. 1 is mounted on the display panel DP, and may be disposed in the non-display area NDA. In other embodiments, the gate driver 120 may be implemented as an integrated circuit distinguished from the display panel DP. In some embodiments, the temperature sensor 160 may be disposed in the non-display area NDA to sense a temperature of the display panel DP.

The pads PD may be disposed in the non-display area NDA on the substrate SUB. The pads PD may be electrically connected to the sub-pixels SP through the lines. For example, the pads PD may be connected to the sub-pixels SP through the first to nth data lines DL1 to DLn.

The pads PD may interface the display panel DP with other components of the display device 100 (see FIG. 1). In some embodiments, voltages and signals, which are necessary for operations of components included in the display panel DP, may be provided from the driver integrated circuit DIC shown in FIG. 1 through the pads PD. For example, the first to nth data lines DL1 to DLn may be connected to the driver integrated circuit DIC through the pads PD. For example, the first and second power voltages VDD and VSS may be received from the driver integrated circuit DIC through the pads PD. When the gate driver 120 is mounted in the display panel DP, the gate control signal GCS may be transmitted from the driver integrated circuit DIC to the gate driver 120 through the pads PD.

In some embodiments, a circuit board may be electrically connected to the pads PD, using a conductive adhesive member such as an anisotropic conductive film. The circuit board may be a Flexible Printed Circuit Board (FPCB) or a flexible film, which has a flexible material. The driver integrated circuit DIC may be mounted on the circuit board to be electrically connected to the pads PD.

In some embodiments, the display area DA may have various shapes. The display area DA may have a closed-loop shape including linear sides and/or curved sides. For example, the display area DA may have shapes such as a polygon, a circle, a semicircle, and an ellipse.

In some embodiments, the display panel DP may have a flat display surface. In other embodiments, the display panel DP may at least partially have a round display surface. In some embodiments, the display panel DP may be bendable, foldable or rollable. The display panel DP and/or the substrate SUB may include materials having flexibility.

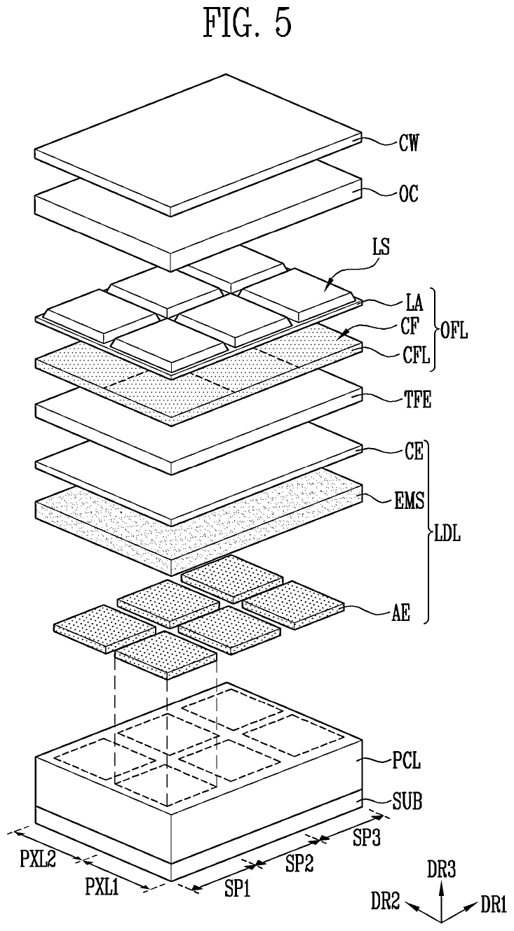

FIG. 5 is an exploded perspective view illustrating a portion of the display panel shown in FIG. 4. In FIG. 5, for clear and brief description, a portion of the display panel DP, which corresponds to two pixels PXL1 and PXL2 among the pixels PXL shown in FIG. 4, may be schematically illustrated. A portion of the display panel DP, which corresponds to the other pixels, may also be configured identically.

Referring to FIGS. 4 and 5, each of first and second pixels PXL1 and PXL2 may include first to third sub-pixels SP1, SP2, and SP3. However, embodiments of the present disclosure are not limited thereto. For example, each of the first and second pixels PXL1 and PXL2 may include four sub-pixels or include two sub-pixels.

In FIG. 5, it may be illustrated that the first to third sub-pixels SP1 to SP3 may have quadrangular shapes when viewed in a third direction DR3 intersecting the first and second directions DR1 and DR2, and have the same size. However, embodiments of the present disclosure are not limited thereto. The first to third sub-pixels SP1 to SP3 may be modified to have various shapes.

The display panel DP may include a substrate SUB, a pixel circuit layer PCL, a light emitting element layer LDL, an encapsulation layer TFE, an optical functional layer OFL, an overcoat layer OC, and a cover window CW.

In some embodiments, the substrate SUB may include a silicon wafer substrate formed using a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, a Silicon On Insulator (SOI) layer, a Semiconductor On Insulator (SeOI) layer, or the like. In other embodiments, the substrate SUB may include a glass substrate. In still other embodiments, the substrate SUB may include a polyimide (PI) substrate.

The pixel circuit layer PCL may be disposed on the substrate SUB. The substrate SUB and/or the pixel circuit layer PCL may include insulating layers and electrode patterns disposed between the insulating layers. The electrode patterns of the pixel circuit layer PCL may serve as at least some of circuit elements, lines, and the like. The electrode patterns may include copper, but embodiments of the present disclosure are not limited thereto.

The circuit elements may include a sub-pixel circuit SPC (see FIG. 2) of each of the first to third sub-pixels SP1, SP2, and SP3. The sub-pixel circuit SPC may include transistors and one or more capacitors. Each transistor may include a semiconductor portion including a source region, a drain region, and a channel region, and a gate electrode overlapping with the semiconductor portion. In some embodiments, when the substrate SUB is provided as a silicon substrate, the semiconductor portion may be included in the substrate SUB, and the gate electrode may be included as an electrode pattern of the pixel circuit layer PCL in the pixel circuit layer PCL. In some embodiments, when the substrate SUB is provided as a glass substrate or a PI substrate, the semiconductor portion and the gate electrode may be included in the pixel circuit layer PCL. Each capacitor may include electrodes spaced apart from each other. For example, each capacitor may include electrodes spaced apart from each other on a plane defined by the first and second directions DR1 and DR2. For example, the capacitor may include electrodes spaced apart from each other in the third direction DR3 with an insulating layer interposed therebetween.

The lines of the pixel circuit layer PCL may include signal lines, e.g., a gate line, an emission control line, a data line, and the like, which are connected to each of the first to third sub-pixels SP1, SP2, and SP3. The lines may further include a line connected to the first power voltage node VDDN shown in FIG. 2. The lines may further include a line connected to the second power voltage node VSSN shown in FIG. 2.

The light emitting element layer LDL may include anode electrodes AE, a light emitting structure EMS, and a cathode electrode CE.

The anode electrodes AE may be disposed on the pixel circuit layer PCL. The anode electrodes AE may be electrically connected to the circuit elements of the pixel circuit layer PCL. The anode electrodes AE may include an opaque conductive material capable of reflecting light, but embodiments of the present disclosure are not limited thereto.

The light emitting structure EMS may be disposed on the anode electrodes AE. The light emitting structure EMS may include a light emitting layer configured to generate light, an electron transport layer configured to transport electrons, a hole transport layer configured to transport holes, and the like.

In some embodiments, the light emitting structure EMS may extend throughout the first to third sub-pixels SP1 to SP3. At least some of the layers in the light emitting structure EMS may be at least partially separated (or cut) or curved at boundaries between the first to third sub-pixels SP1 to SP3. However, embodiments are not limited thereto.

The cathode electrode CE may be disposed on the light emitting structure EMS. The cathode electrode CE may extend throughout the first to third sub-pixels SP1 to SP3. As such, the cathode electrode CE may be provided as a common electrode for the first to third sub-pixels SP1 to SP3.

The cathode electrode CE may be a thin metal layer having a thickness to a degree to which light emitted from the light emitting structure EMS can be transmitted therethrough. The cathode electrode CE may be formed of a metal material to have a relatively thin thickness or be formed of a transparent conductive material. In some embodiments, the cathode electrode CE may include at least one of various transparent conductive materials including indium tin oxide, indium zinc oxide, indium tin zinc oxide, aluminum zinc oxide, gallium zinc oxide, zinc tin oxide, and gallium tin oxide. In other embodiments, the cathode electrode CE may include at least one of silver (Ag), magnesium (Mg), and mixtures thereof. However, the material of the cathode electrode CE is not limited thereto.

It may be understood that any one of the anode electrodes AE, a portion of the light emitting structure EMS, which overlaps therewith, and a portion of the cathode electrode CE, which overlaps therewith, constitute one light emitting element LD (see FIG. 2). Each light emitting element of the first to third sub-pixels SP1 to SP3 may include one anode electrode AE, a portion of the light emitting structure EMS that overlaps the anode electrode AE, and a portion of the cathode electrode CE that overlaps the portion of the light emitting structure EMS. In each of the first to third sub-pixels SP1 to SP3, holes injected from the anode electrode AE and electrons injected from the cathode electrode CE may be transported into a light emitting layer of the light emitting structure EMS to form excitons, and light may be generated when the excitons are changed from an excited state to a ground state. A luminance of the light may be determined according to an amount of current flowing through the light emitting layer. A wavelength band of the generated light may be determined according to a configuration of the light emitting layer.

The encapsulation layer TFE may be disposed over the cathode electrode CE. The encapsulation layer TFE may cover the light emitting element layer LDL and/or the pixel circuit layer PCL. The encapsulation layer TFE may be configured to prevent oxygen and/or moisture from infiltrating into the light emitting element layer LDL. In some embodiments, the encapsulation layer TFE may include a structure in which at least one inorganic layer and at least one organic layer are alternately stacked. For example, the inorganic layer may include silicon nitride, silicon oxide, silicon oxynitride (SiOₓN_{y}), or the like. For example, the organic layer may include an organic insulating material such as acrylic resin, epoxy resin, phenolic resin, polyamide resin, polyimide resin, unsaturated polyester resin, polyphenylene resin, polyphenylenesulfide resin, or benzocyclobutene (BCB). However, the materials of the organic layer and the inorganic layer of the encapsulation layer TFE are not limited thereto.

In order to improve encapsulation efficiency of the encapsulation layer TFE, the encapsulation layer TFE may further include a thin film including aluminum oxide (AlOₓ). The thin film including the aluminum oxide may be located on a top surface of the encapsulation layer TFE, which faces the optical functional layer OFL, and/or a bottom surface of the encapsulation layer TFE, which faces the light emitting element layer LDL.

The thin film including the aluminum oxide may be formed through an Atomic Layer Deposition (ALD) process. However, embodiments of the present disclosure are not limited thereto. The encapsulation layer TFE may further include a thin film formed of at least one of various materials suitable for the improvement of the encapsulation efficiency.

The optical functional layer OFL may be disposed on the encapsulation layer TFE. The optical functional layer OFL may include a color filter layer CFL and a lens array LA.

The color filter layer CFL may be disposed between the encapsulation layer TFE and the lens array LA. The color filter layer CFL may be configured filter light emitted from the light emitting structure EMS, thereby selectively outputting light of a wavelength band or a color, which corresponds to each sub-pixel. The color filter layer CFL may include color filters CF respectively corresponding to the first to third sub-pixels SP1 to SP3. Each of the color filters CF may allow light having a wavelength band corresponding to a corresponding sub-pixel to pass therethrough. For example, a color filter corresponding to the first sub-pixel SP1 may allow light of a red color to pass therethrough, a color filter corresponding to the second sub-pixel SP2 may allow light of a green color to pass therethrough, and a color filter corresponding to the third sub-pixel SP3 may allow light of a blue color to pass therethrough. According to light emitted from the light emitting structure EMS in each sub-pixel, at least some of the color filters CF may be omitted.

The lens array LA may be disposed on the color filter layer CFL. The lens array LA may include lenses LS respectively corresponding to the first to third sub-pixels SP1 to SP3. Each of the lenses LS may output light emitted from the light emitting structure EMS along an intended path, thereby improving light emission efficiency. The lens array LA may have a relatively high refractive index. For example, the lens array LA may have a refractive index higher than a refractive index of the overcoat layer OC. In some embodiments, the lenses LS may include an organic material. In other embodiments, the lenses LS may include an acryl-based material. However, the lenses LS are not limited to these material.

The overcoat layer OC may be disposed over the lens array LA. The overcoat layer OC may cover the optical functional layer OFL, the encapsulation layer TFE, the light emitting structure EMS, and/or the pixel circuit layer PCL. The overcoat layer OC may include various materials suitable for protecting lower layers thereof from foreign matters such as dust and moisture. For example, the overcoat layer OC may include at least one of an inorganic insulating layer and an organic insulating layer. For example, the overcoat layer OC may include epoxy, but embodiments of the present disclosure are not limited thereto. The overcoat layer OC may have a refractive index lower than a refractive index of the lens array LA.

The cover window CW may be disposed on the overcoat layer OC. The cover window CW may be configured to protect lower layers thereof. The cover window CW may have a refractive index higher than the refractive index of the overcoat layer OC. The cover window CW may include glass, but embodiments of the present disclosure are not limited thereto. For example, the cover window CW may be an encapsulation glass configured to protect components disposed on the bottom thereof. In other embodiments, the cover window CW may be omitted.

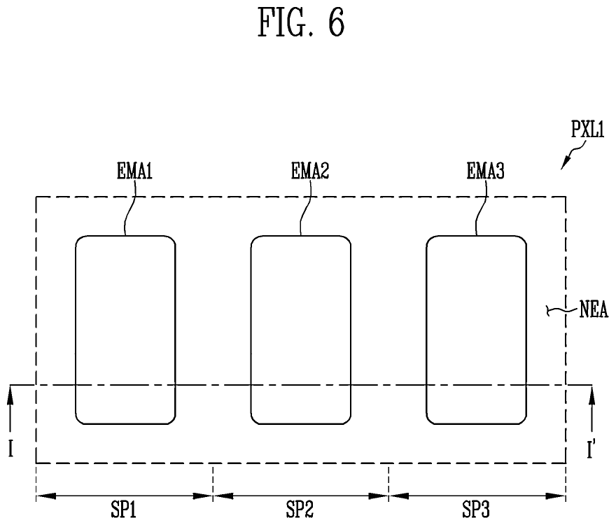

FIG. 6 is a plan view illustrating an embodiment of any one of the pixels shown in FIG. 5. In FIG. 6, for clear and brief description, the first pixel PXL1 among the first and second pixels PXL1 and PXL2 shown in FIG. 5 may be schematically illustrated. The other pixels may be configured identically to the first pixel PXL1.

Referring to FIGS. 5 and 6, the first pixel PXL1 may include first to third sub-pixels SP1 to SP3 arranged in the first direction DR1.

The first sub-pixel SP1 may include a first emission area EMA1 and a non-emission area NEA at the periphery of the first emission area EMA1. The second sub-pixel SP2 may include a second emission area EMA2 and the non-emission area at the periphery of the second emission area EMA2. The third sub-pixel SP3 may include a third emission area EMA3 and the non-emission area at the periphery of the third emission area EMA3.

The first emission area EMA1 may be an area in which light is emitted from a portion of the light emitting structure EMS (see FIG. 5), which corresponds to the first sub-pixel SP1. The second emission area EMA2 may be an area in which light is emitted from a portion of the light emitting structure EMS, which corresponds to the second sub-pixel SP2. The third emission area EMA3 may be an area in which light is emitted from a portion of the light emitting structure EMS, which corresponds to the third sub-pixel SP3.

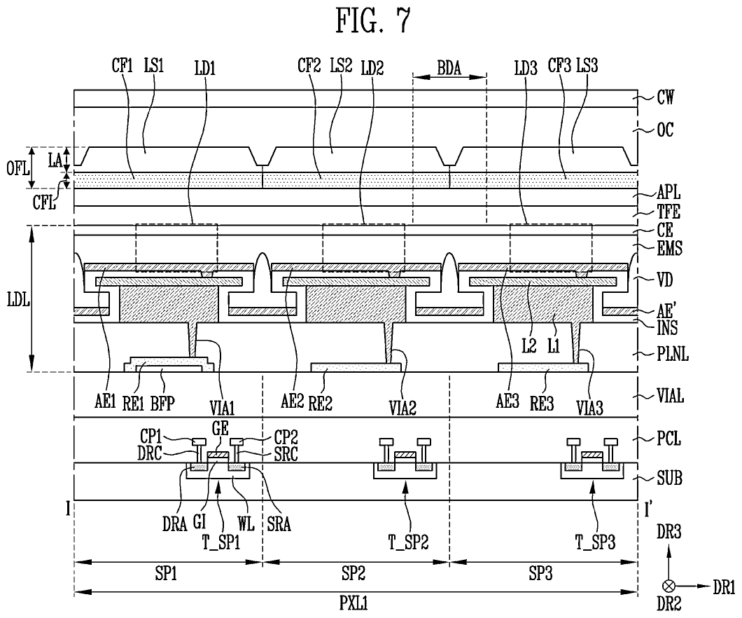

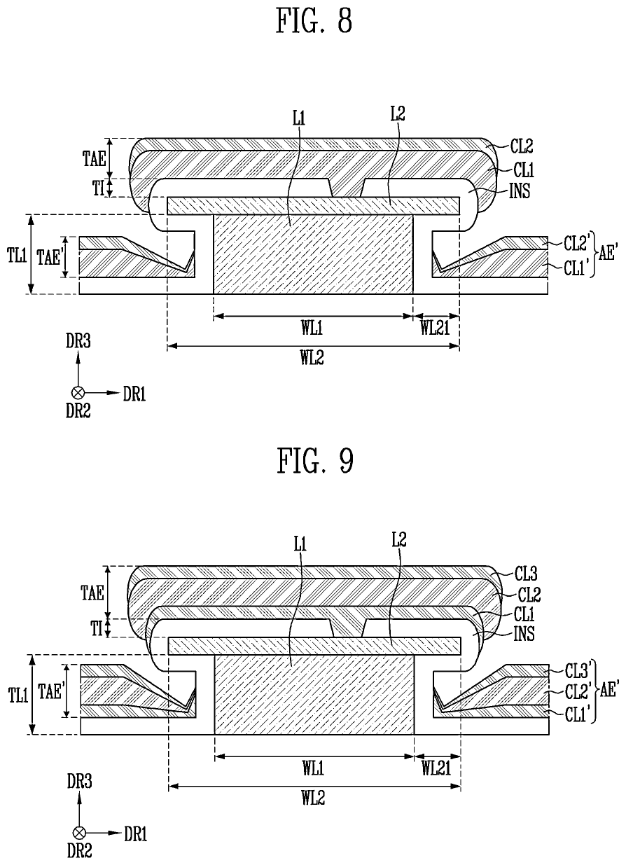

FIG. 7 is a cross-sectional view illustrating an embodiment taken along line I-I′ shown in FIG. 6. FIG. 8 is a cross-sectional view illustrating an embodiment of an anode electrode shown in FIG. 7. FIG. 9 is a cross-sectional view illustrating another embodiment of the anode electrode shown in FIG. 7.

Referring to FIG. 7, a pixel circuit layer PCL may be provided on a substrate SUB. The substrate SUB may include a silicon wafer substrate formed using a semiconductor process. For example, the substrate SUB may include silicon, germanium, and/or silicon-germanium.

The substrate SUB and the pixel circuit layer PCL may include circuit elements of each of first to third sub-pixels SP1 to SP3. For example, the substrate SUB and the pixel circuit layer PCL may include a transistor T_SP1 of the first sub-pixel SP1, a transistor T_SP2 of the second sub-pixel SP2, and a transistor T_SP3 of the third sub-pixel SP3. The transistor T_SP1 of the first sub-pixel SP1 may be any one of transistors included in a sub-pixel circuit SPC (see FIG. 2) of the first sub-pixel SP1, the transistor T_SP2 of the second sub-pixel SP2 may be any one of transistors included in a sub-pixel circuit SPC of the second sub-pixel SP2, and the transistor T_SP3 of the third sub-pixel SP3 may be any one of transistors included in a sub-pixel circuit SPC of the third sub-pixel SP3. In FIG. 7, for clear and brief description, one of the transistors of each sub-pixel is illustrated, and the other circuit elements are omitted.

The transistors T_SP1 of the first sub-pixel SP1 may include a source region SRA, a drain region DRA, and a gate electrode GE.

The source region SRA and the drain region DRA may be disposed in the substrate SUB. A well WL formed through an ion implantation process may be disposed in the substrate SUB, and the source region SRA and the drain region DRA may be disposed in the well WL to be spaced apart from each other. A region between the source region SRA and the drain region DRA in the well WL may be defined as a channel region.

The gate electrode GE may overlap with the channel region between the source region SRA and the drain region DRA, and be disposed in the pixel circuit layer PCL. The gate electrode GE may be spaced apart from the well WL or the channel region by an insulating material such as a gate insulating layer GI. The gate electrode GE may include a conductive material.

A plurality of layers included in the pixel circuit layer PCL may include insulating layers and electrode patterns disposed between the insulating layers, and the electrode patterns may include first and second electrode patterns CP1 and CP2. The first electrode pattern CP1 may be electrically connected to the drain region DRA through a drain connection portion DRC that extends through one or more insulating layers. The second electrode pattern CP2 may be electrically connected to the source region SRA through a source connection portion SRC that extends through one or more insulating layers.

As the gate electrode GE and the first and second electrode patterns CP1 and CP2 are connected to other circuit elements and/or lines, the transistor T_SP1 of the first sub-pixel SP1 may be provided as any one of the transistors of the first sub-pixel SP1.

Each of the transistor T_SP2 of the second sub-pixel SP2 and the transistor T_SP3 of the third sub-pixel SP3 may be configured identically to the transistor T_SP1 of the first sub-pixel SP1.

As such, the substrate SUB and/or the pixel circuit layer PCL may include circuit elements of each of the first to third sub-pixels SP1 to SP3.

A via layer VIAL may be disposed on the pixel circuit layer PCL. The via layer VIAL covers the pixel circuit layer PCL, and may have a flat surface (e.g., the entire surface of the via layer VIAL may be flat). The via layer VIAL may include at least one of silicon oxide (SiOₓ), silicon nitride (SiNₓ), and silicon carbon nitride (SiCN), but embodiments of the present disclosure are not limited thereto.

A light emitting element layer LDL may be disposed on the via layer VIAL. The light emitting element layer LDL may include first to third reflective electrodes RE1 to RE3, a planarization layer PLNL, a first separation layer L1, a second separation layer L2, an insulating layer INS, first to third anode electrodes AE1 to AE3, a light emitting structure EMS, and a cathode electrode CE.

The first to third reflective electrodes RE1 to RE3 are respectively disposed in the first to third sub-pixels SP1 to SP3 on the via layer VIAL. Each of the first to third reflective electrodes RE1 to RE3 may be in contact with a circuit element disposed in the pixel circuit layer PCL through a via extending through the via layer VIAL.

The first to third reflective electrodes RE1 to RE3 may serve as full mirrors which reflect light emitted from the light emitting structure EMS toward a display surface (or a cover window CW). The first to third reflective electrodes RE1 to RE3 may include a metal material suitable for reflecting light. The first to third reflective electrodes RE1 to RE3 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and alloys of two or more materials selected therefrom, but embodiments of the present disclosure are not limited thereto.

In some embodiments, a connection electrode may be disposed on the bottom of each of the first to third reflective electrodes RE1 to RE3. The connection electrode may improve an electrical connection characteristic between a corresponding reflective electrode and a circuit element of the pixel circuit layer PCL. The connection electrode may have a multi-layer structure. The multi-layer structure may include titanium (Ti), titanium nitride (TiN), tantalum nitride (TaN), and the like, but embodiments of the present disclosure are not limited thereto. In some embodiments, a corresponding reflective electrode may be located between multiple layers of the connection electrode.

A buffer pattern BFP may be disposed on the bottom of at least one of the first to third reflective electrodes RE1 to RE3. The buffer pattern BFP may include an inorganic material such as silicon carbon nitride, but embodiments of the present disclosure are not limited thereto. A height of the reflective electrode in the third direction DR3 may be controlled with the position of the buffer pattern BFP. For example, the buffer pattern BFP may be disposed between the first reflective electrode RE1 and the via layer VIAL, changing the height of the first reflective electrode RE1.

The first to third reflective electrodes RE1 to RE3 may serve as full mirrors, and the cathode electrode CE may serve as a half mirror. Light emitted from a light emitting layer of the light emitting structure EMS may be amplified by at least partially reciprocating between a corresponding reflective electrode and the cathode electrode CE, and the amplified light may be output through the cathode electrode CE. As such, a distance between each reflective electrode and the cathode electrode CE may be understood as a resonance distance of light emitted from the light emitting layer of the corresponding light emitting structure EMS.

By the buffer pattern BFP, the first sub-pixel SP1 may have a resonance distance shorter than a resonance distance of another sub-pixel. Light in a specific wavelength range (e.g., a red color) may be effectively and efficiently amplified by the adjusted resonance distance. Accordingly, the first sub-pixel SP1 can effectively and efficiently output light of the predetermined wavelength range.

In FIG. 7, it is illustrated the buffer pattern BFP is provided between the first sub-pixel SP1 and the via layer VIAL but not provided for the second and third sub-pixels SP2 and SP3. However, this is not a limitation of the disclosure. The buffer pattern may be provided for one or both of the second and third sub-pixels SP2 and SP3, to adjust a resonance distance of the at least one of the second and third sub-pixels SP2 and SP3. For example, the first to third sub-pixels SP1 to SP3 may respectively correspond to red, green, and blue. A distance between the first reflective electrode RE1 and the cathode electrode CE may be shorter than a distance between the second reflective electrode RE2 and the cathode electrode CE, and the distance between the second reflective electrode RE2 and the cathode electrode CE may be shorter than a distance between the third reflective electrode RE3 and the cathode electrode CE.

The planarization layer PLNL may be disposed on the via layer VIAL and the first to third reflective electrodes RE1 to RE3 to planarize step differences between the first to third reflective electrodes RE1 to RE3. The planarization layer PLNL entirely covers the first to third reflective electrodes RE1 to RE3 and the via layer VIAL, and may have a flat surface. In some embodiments, the planarization layer PLNL may be omitted.

The first separation layer L1 may be disposed in the first to third emission areas EMA1 to EMA3 (see FIG. 6). The first separation layer L1 may be disposed on the planarization layer PLNL. The first separation layer L1 may be disposed directly on the planarization layer PLNL. First separation layers L1 in each of the first to third sub-pixels SP1 to SP3 may be electrically connected to the first to third reflective electrodes RE1 to RE3 disposed thereunder through vias extending through the planarization layer PLNL, respectively. The first separation layer L1 of the first sub-pixel SP1 may be electrically connected to the first reflective electrode RE1 through a first via VIA1 that extends through the planarization layer PLNL. The first separation layer L1 of the second sub-pixel SP2 may be electrically connected to the second reflective electrode RE2 through a second via VIA2 that extends through the planarization layer PLNL. The first separation layer L1 of the third sub-pixel SP3 may be electrically connected to the third reflective electrode RE3 through a third via VIA3 that extends through the planarization layer PLNL. The first separation layers L1 of the first to third sub-pixels SP1 to SP3 may be electrically connected to the pixel circuit layer PCL respectively through the first to third reflective electrodes RE1 to RE3. In an embodiment, the first separation layer L1 may include a conductive material. In an example, the first separation layer L1 may include at least one of aluminum (Al), silver (Ag), magnesium (Mg), platinum (Pt), palladium (Pd), gold (Au), nickel (Ni), neodymium (Nd), iridium (Ir), chromium (Cr), and alloys of two or more materials selected therefrom, but embodiments of the present disclosure are not limited to the material that is explicitly mentioned above.

The second separation layer L2 may be disposed on the first separation layer L1. The second separation layer L2 may be disposed directly on the first separation layer L1. The second separation layer L2 may be electrically connected to the first separation layer L1. The second separation layer L2 may be electrically connected to the pixel circuit layer PCL through the first separation layer L1 and the first to third reflective electrodes RE1 to RE3. In an embodiment, the second separation layer L2 may include a conductive material. In an example, the second separation layer L2 may include at least one of aluminum (Al), silver (Ag), magnesium (Mg), platinum (Pt), palladium (Pd), gold (Au), nickel (Ni), neodymium (Nd), iridium (Ir), chromium (Cr), and alloys of two or more materials selected therefrom, but embodiments of the present disclosure are not limited to the material that is explicitly mentioned above.

The insulating layer INS may be disposed over the first separation layer L1 and the second separation layer L2. The insulating layer INS may cover the side surfaces of the first separation layer L1 and the top surface, side surfaces, and the bottom surfaces of the overhang of the second separation layer L2. The insulating layer INS covering the first separation layer L1 and the second separation layer L2 prevents a conductive pattern AE′ (or a second area of a first electrode), which will be described later, from contacting the first separation layer L1 and the second separation layer L2. The insulating layer INS may function to electrically separate the conductive pattern AE′ from the first separation layer L1, the second separation layer L2, and/or the first to third anode electrodes AE1, AE2, and AE3. The insulating layer INS may include various kinds of inorganic insulating materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ), but the present disclosure is not necessarily limited to the material that is explicitly disclosed above.

The first to third anode electrodes AE1, AE2, and AE3 make up a first area of the first electrode, and the conductive pattern AE′ make up the second area of the first electrode. The first area and the second area of the first electrode AE may be disposed on the insulating layer INS. The first to third anode electrodes AE1, AE2, and AE3 and the conductive pattern AE′ may include the same material. The first to third anode electrodes AE1, AE2, and AE3 and the conductive pattern AE′ may be simultaneously formed through the same process, but the present disclosure is not necessarily limited thereto.

The first to third anode electrodes AE1, AE2, and AE3 may be separated from the conductive pattern AE′ by the first separation layer L1, the second separation layer L2, and the insulating layer INS. Accordingly, the first to third anode electrodes AE1, AE2, and AE3 and the conductive pattern AE′ may be electrically separated from each other. The first to third anode electrodes AE1, AE2, and AE3 may be disposed on the first separation layer L1 and the second separation layer L2. The first to third anode electrodes AE1, AE2, and AE3 may overlap with the first separation layer L1 and the second separation layer L2 in the third direction DR3.

In an embodiment, the first to third anode electrodes AE1, AE2, and AE3 may be separated from the conductive pattern AE′ by a T-shaped structure formed by the first separation layer L1 and the second separation layer L2. In an example, the first to third anode electrodes AE1, AE2, and AE3 as the first area of the first electrode may be formed on the first separation layer L1 and the second separation layer L2 by entirely depositing the first electrode, and the conductive pattern AE′ as the second area separated from the first area of the first electrode may be formed at boundaries between the first to third sub-pixels SP1 to SP3. A separate etching process for separating the first to third sub-pixels SP1 to SP3 from each other is unnecessary, and an ultra high definition display device can be implemented.

The conductive pattern AE′ may be disposed between the first separation layers L1 of the first to third sub-pixels SP1 to SP3. The conductive pattern AE′ may be disposed between the second separation layers L2 of the first to third sub-pixels SP1 to SP3. The conductive pattern AE′ may be disposed at the boundaries between the first to third sub-pixels SP1 to SP3. The conductive pattern AE′ may be disposed in a boundary area BDA between sub-pixels.

The first to third anode electrodes AE1, AE2, and AE3 may overlap with the first to third reflective electrodes RE1 to RE3 in the third direction DR3, respectively. The first to third anode electrodes AE1 to AE3 may have shapes similar to the shapes of the first to third emission areas EMA1 to EMA3 shown in FIG. 6 when viewed in the third direction DR3.

Each of the first to third anode electrodes AE1, AE2, and AE3 may be electrically connected to the second separation layer L2 through a contact hole extending through the insulating layer INS. The first to third anode electrodes AE1, AE2, and AE3 may be electrically connected to the pixel circuit layer PCL through the second separation layer L2, the first separation layer L1, and the first to third reflective electrodes RE1 to RE3. The first anode electrode AE1 may be electrically connected to the second separation layer L2 of the first sub-pixel SP1 through a contact hole extending through the insulating layer INS. The second anode electrode AE2 may be electrically connected to the second separation layer L2 of the second sub-pixel SP2 through a contact hole extending through the insulating layer INS. The third anode electrode AE2 may be electrically connected to the second separation layer L2 of the third sub-pixel SP3 through a contact hole extending through the insulating layer INS.

In some embodiments, the first to third anode electrodes AE1 to AE3 may include at least one of transparent conductive materials such as indium tin oxide (ITO), indium zinc oxide (IZO), zinc oxide (ZnO), indium gallium zinc oxide (IGZO), and indium tin zinc oxide (ITZO). However, the material of the first to third anode electrodes AE1 to AE3 is not limited thereto. For example, the first to third anode electrodes AE1 to AE3 may include titanium nitride.

In an embodiment, a void VD may be formed in the boundary area BDA. The void VD may cause a discontinuity in the light emitting structure EMS. For example, the light emitting structure EMS may be at least partially separated (or cut) or curved in the boundary area BDA by the void VD.

The void VD may be disposed between the first separation layers L1 of the first to third sub-pixels SP1 to SP3. The void VD may be disposed between the second separation layers L2 of the first to third sub-pixels SP1 to SP3. The void VD may be disposed between the first to third anode electrodes AE1, AE2, and AE3. The void VD may be disposed on the conductive pattern AE′. The void VD may be immediately adjacent to the conductive pattern AE′ in the third direction DR3. Some or all of a plurality of layers included in the light emitting structure EMS may be at least partially separated or curved in the boundary area BDA by the void VD. For example, at least one charge generation layer included in the light emitting structure EMS may be separated from an adjacent charge generation layer in the boundary area BDA by the void VD.

Referring to FIG. 8, a thickness TAE of the anode electrode AE in the third direction DR3 may be equal to a thickness TAE′ of the conductive pattern AE′ in the third direction DR3. In some embodiments, the thickness of the conductive pattern AE′ may become thinner as the distance to the first conductive layer L1 decreases, but increase close to the insulating layer INS, such that the portion of the conductive pattern AE′ that contacts the insulating layer INS may be thicker than a portion that is some distance away. However, the change in the thickness of the conductive pattern AE′ is not necessarily limited to what is depicted in FIG. 8, and may be variously changed in some embodiments.

A width WL1 of the first separation layer L1 in the first direction DR1 may be smaller than a width WL2 of the second separation layer L2 in the first direction DR1. The second separation layer L2 may completely overlap with the first separation layer L1. One side of the second conductive layer L2 may extend beyond an edge of the first separation layer L1 in the first direction DR1. The other side of the second separation layer L2 may extend beyond the other side of the first separation layer L1 in the negative first direction DR1. That is, the first separation layer L1 and the second separation layer L2 may form a T-shaped structure. A width WL21 is the distance by which the second separation layer L2 extends beyond the first separation layer L1 in the first direction DR1, and the width WL21 may be greater than the thickness TAE of the anode electrode AE in the third direction DR3 or the thickness TAE′ of the conductive pattern AE′ in the third direction DR3. A thickness TL1 of the first separation layer L1 in the third direction DR3 may be greater than a sum of a thickness TI of the insulating layer INS and the thickness TAE of the anode electrode AE in the third direction DR3. The thickness TL1 of the first separation layer L1 in the third direction DR3 may be greater than a sum of the thickness TI of the insulating layer INS in the third direction DR3 and the thickness TAE′ of the conductive pattern AE′ in the third direction DR3. When the first separation layer L1, the second separation layer L2, the insulating layer INS, and/or the anode electrode AE are formed with the thicknesses and widths, which are shown in FIG. 8, the first to third anode electrode AE1, AE2, and AE3 may be separated from the conductive pattern AE′ by the T-shaped structure formed by the first separation layer L1 and the second separation layer L2.

The anode electrode AE and the conductive pattern AE′ may include two or more conductive layers. For example, the anode electrode AE may include a first electrode layer CL1 and a second electrode layer CL2 disposed on the first electrode layer CL1. The conductive pattern AE′ may include a first electrode layer CL1′ and a second electrode layer CL2′ disposed on the first electrode layer CL1′. Each of the first electrode layers CL1 and CL1′ may be disposed between the insulating layer INS and each of the second electrode layers CL2 and CL2′. Each of the second electrode layers CL2 and CL2′ may be disposed directly on each of the first electrode layers CL1 and CL1′.

Each of the first electrodes CL1 and CL1′ may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and alloys of two or more materials selected therefrom, but embodiments of the present disclosure are not limited thereto.

Each of the second electrode layers CL2 and CL2′ may include at least one of transparent conductive materials such as indium tin oxide (ITO), indium zinc oxide (IZO), zinc oxide (ZnO), indium gallium zinc oxide (IGZO), and indium tin zinc oxide (ITZO), but embodiments of the present disclosure are not limited thereto.

Referring to FIG. 9, the anode electrode AE may include a first electrode layer CL1, a second electrode layer CL2 disposed on the first electrode layer CL1, and a third electrode layer CL3 disposed on the second electrode layer CL2. The conductive pattern AE′ may include a first electrode layer CL1′, a second electrode layer CL2′ disposed on the first electrode layer CL1′, and a third electrode layer CL3′ disposed on the second electrode layer CL2′. The first electrode layers CL1 and CL1′ may be disposed between the insulating layer INS and the second electrode layers CL2 and CL2′, respectively. The second electrode layer CL2 may be disposed between the first electrode layer CL1 and the third electrode layer CL3, and the second electrode layer CL2′ may be disposed between the first electrode layer CL1′ and the third electrode layer CL3′. The second electrode layers CL2 and CL2′ may be disposed directly on the first electrode layers CL1 and CL1′, respectively. The third electrode layers CL3 and CL3′ may be disposed directly on the second electrode layers CL2 and CL2′, respectively.

Each of the first electrodes CL1 and CL1′ may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and alloys of two or more materials selected therefrom, but embodiments of the present disclosure are not limited thereto.

Each of the second electrode layers CL2 and CL2′ may include at least one of transparent conductive materials such as indium tin oxide (ITO), indium zinc oxide (IZO), zinc oxide (ZnO), indium gallium zinc oxide (IGZO), and indium tin zinc oxide (ITZO), but embodiments of the present disclosure are not limited thereto.

Each of the third electrode layers CL3 and CL3′ may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and alloys of two or more materials selected therefrom, but embodiments of the present disclosure are not limited thereto.

The first electrode layers CL1 and CL1′ and the third electrode layers CL3 and CL3′ may include the same material, but this is not a limitation of the present disclosure.

Referring back to FIG. 7, the light emitting structure EMS may be disposed on the first to third anode electrodes AE1, AE2, and AE3 and the conductive pattern AE′. The light emitting structure EMS may be disposed continuously across the first to third sub-pixels SP1 to SP3. Some or all of a plurality of layers included in the light emitting structure EMS may be at least partially separated or curved on the conductive pattern AE′. Some or all of the plurality of layers included in the light emitting structure EMS may be at least partially separated or curved in the boundary area BDA by the void VD. For example, at least one charge generation layer included in the light emitting structure EMS may be separated from a neighboring charge generation layer in the boundary area BDA by the void VD. Accordingly, in an operation of the display panel DP, a current leaked from each of the first to third sub-pixels SP1 to SP3 to a sub-pixel adjacent to each of the first to third sub-pixels SP1 to SP3 through the layers included in the light emitting structure EMS can decrease. Thus, first to third light emitting elements LD1 to LD3 can operate with relatively high reliability.

The cathode electrode CE may be disposed on the light emitting structure EMS. The cathode electrode CE may be commonly provided in the first to third sub-pixels SP1 to SP3. The cathode electrode CE may serve as a half mirror which allows light emitted from the light emitting structure EMS to be partially transmitted therethrough and allows light emitted from the light emitting structure EMS to be partially reflected therefrom.

The cathode electrode CE may be connected to the light emitting structure EMS in the boundary area BDA to be commonly provided in the first to third sub-pixels SP1 to SP3. The cathode electrode CE may be connected above the conductive pattern AE′ in the boundary area BDA. The cathode electrode CE may be connected above the void VD in the boundary area BDA.

The first anode electrode AE1, a portion of the light emitting structure EMS that overlaps with the first anode electrode AE1, and a portion of the cathode electrode CE that overlaps with the first anode electrode AE1 may constitute the first light emitting elements LD1. The second anode electrode AE2, a portion of the light emitting structure EMS that overlaps with the second anode electrode AE2, and a portion of the cathode electrode CE that overlaps with the second anode electrode AE2 may constitute the second light emitting elements LD2. The third anode electrode AE3, a portion of the light emitting structure EMS that overlaps with the third anode electrode AE3, and a portion of the cathode electrode CE that overlaps with the third anode electrode AE3 may constitute the third light emitting elements LD3.

An encapsulation layer TFE may be disposed over the cathode electrode CE. The encapsulation layer TFE may prevent oxygen and/or moisture from infiltrating into the light emitting element layer LDL.

An optical functional layer OFL may be disposed on the encapsulation layer TFE. In some embodiments, the optical functional layer OFL may be attached to the encapsulation layer TFE through an adhesive layer APL. For example, the optical functional layer OFL may be separately manufactured to be attached to the encapsulation layer TFE through the adhesive layer APL. The adhesive layer APL may further perform a function of protecting lower layers including the encapsulation layer TFE.

The optical functional layer OFL may include a color filter layer CFL and a lens array LA. The color filter layer CFL may include first to third color filters CF1 to F3 respectively corresponding to the first to third sub-pixels SP1 to SP3. The first to third color filters CF1 to F3 may allow lights having different wavelength ranges to pass therethrough. For example, the first, second, and third color filters CF1, CF2, and CF3 may allow light of red, green, and blue colors to pass therethrough, respectively.

In some embodiments, the first to third color filters CF1 to CF3 may partially overlap with each other in the boundary area BDA. In other embodiments, the first to third color filters CF1 to CF3 may be spaced apart from each other, and a black matrix may be provided between the first to third color filters CF1 to CF3.

The lens array LA may be disposed on the color filter layer CFL. The lens array LA may include first to third lenses LS1 to LS3 respectively corresponding to the first to third sub-pixels SP1 to SP3. The first to third lenses LS1 to LS3 may respectively output lights emitted from the first to third light emitting layers LD1 to LD3 along intended paths, thereby improving light emission efficiency.

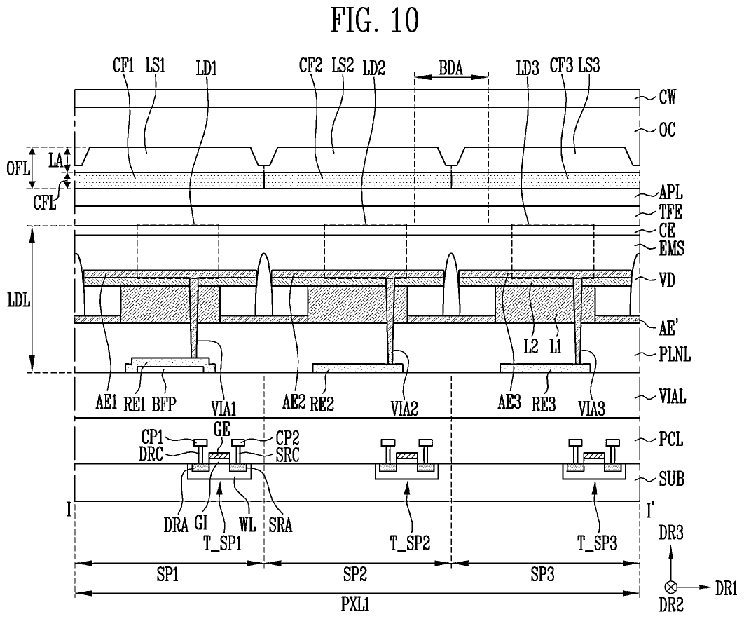

FIG. 10 is a cross-sectional view illustrating another embodiment taken along the line I-I′ shown in FIG. 6.

Referring to FIG. 10, a first separation layer L1 and/or a second separation layer L2 may include an insulating material. For example, the first separation layer L1 and/or the second separation layer L2 may include various kinds of inorganic insulating materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ), but the present disclosure is not necessarily limited to the material that is expressly disclosed above. As such, when the first separation layer L1 and/or the second separation layer L2 are/is formed of an insulating material, the insulating layer INS (see FIG. 7) for electrically separating the first separation layer L1 and/or the second separation layer L2 from a conductive pattern AE′ may be omitted.

First to third anode electrodes AE1, AE2, and AE3 (or a first area of a first electrode) may be disposed directly on the second separation layer L2. The conductive pattern AE′ (or a second area of the first electrode) may be disposed on a planarization layer PLNL. The conductive pattern AE′ may be disposed directly on the planarization layer PLNL. The first conductive pattern AE′ may be disposed in the same layer as the first separation layer L1.

The first to third anode electrodes AE1, AE2, and AE3 may be electrically connected to first to third reflective electrodes RE1 to RE3 through vias that extend through the second separation layer L2, the first separation layer L1, and/or the planarization layer PLNL, respectively. The first to third anode electrodes AE1, AE2, and AE3 may be electrically connected to a pixel circuit layer PCL respectively through the first to third reflective electrodes RE1 to RE3. The first anode electrode AE1 may be electrically connected to the first reflective electrode RE1 through a first via VIA1 that extends through at least one of the second separation layer L2, the first separation layer L1, and the planarization layer PLNL. The second anode electrode AE2 may be electrically connected to the second reflective electrode RE2 through a second via VIA2 that extends through at least one of the second separation layer L2, the first separation layer L1, and the planarization layer PLNL. The third anode electrode AE3 may be electrically connected to the third reflective electrode RE3 through a third via VIA3 that extends through at least one of the second separation layer L2, the first separation layer L1, and/or the planarization layer PLNL. The first to third anode electrodes AE1, AE2, and AE3 may be electrically connected to the pixel circuit layer PCL respectively through the first to third reflective electrodes RE1 to RE3.

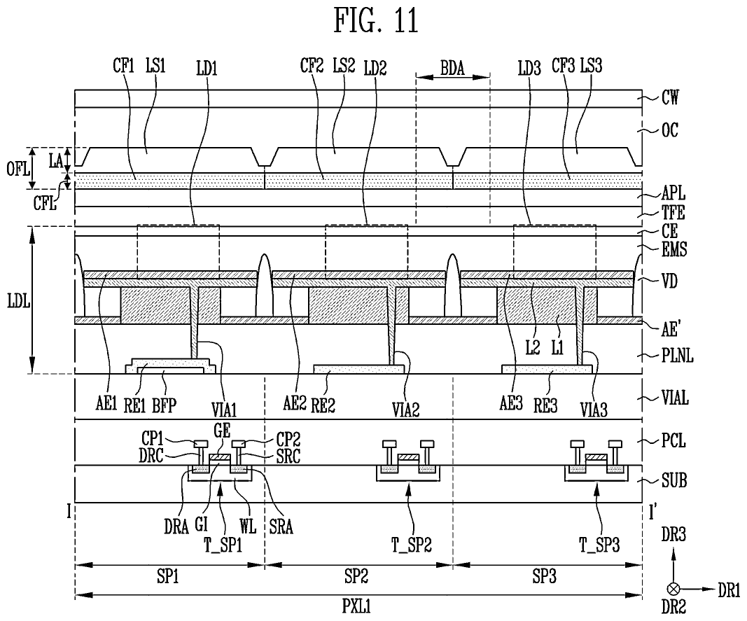

FIG. 11 is a cross-sectional view illustrating still another embodiment taken along the line I-I′ shown in FIG. 6.

Referring to FIG. 11, a first separation layer L1 may include an insulating material. In an example, the first separation layer L1 may include various kinds of inorganic insulating materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ), but the present disclosure is not necessarily limited thereto. As such, when the first separation layer L1 is formed of an insulating material, the insulating layer INS (see FIG. 7) for electrically separating the first separation layer L1 from a conductive pattern AE′ may be omitted. First to third anode electrodes AE1, AE2, and AE3 (or a first area of a first electrode) may be disposed on a second separation layer L2. The first to third anode electrodes AE1, AE2, and AE3 may be disposed directly on the second separation layer L2. The conductive pattern AE′ (or a second area of the first electrode) may be disposed on a planarization layer PLNL. The conductive pattern AE′ may be disposed directly on the planarization layer PLNL. The conductive pattern AE′ may be disposed in the same layer as the first separation layer L1.

The second separation layer L2 may include a conductive material. For example, the second separation layer L2 may include at least one of aluminum (Al), silver (Ag), magnesium (Mg), platinum (Pt), palladium (Pd), gold (Au), nickel (Ni), neodymium (Nd), iridium (Ir), chromium (Cr), and alloys of two or more materials selected therefrom, but embodiments of the present disclosure are not limited thereto. As such, when the second separation layer L2 is formed of a conductive material, second separation layers L2 of first to third sub-pixels SP1 to SP3 may be electrically connected to first to third reflective electrodes RE1 to RE3 through vias that extend through the first separation layer L1 and/or the planarization layer PLNL, respectively. The second separation layer L2 of the first to third sub-pixels SP1 to SP3 may be electrically connected to a pixel circuit layer PCL respectively through the first to third reflective electrodes RE1 to RE3. The second separation layer L2 of the first sub-pixel SP1 may be electrically connected to the first reflective electrode RE1 through a first via VIA1 extending through the first separation layer L1 and/or the planarization layer PLNL. The second separation layer L2 of the second sub-pixel SP2 may be electrically connected to the second reflective electrode RE2 through a second via VIA2 extending through the first separation layer L1 and/or the planarization layer PLNL. The second separation layer L2 of the third sub-pixel SP3 may be electrically connected to the third reflective electrode RE3 through a third via VIA3 extending through the first separation layer L1 and/or the planarization layer PLNL. The second separation layers L2 of the first to third sub-pixels SP1 to SP3 may be electrically connected to the pixel circuit layer PCL respectively through the first to third reflective electrodes RE1 to RE3.

Each of the first to third anode electrodes AE1, AE2, and AE3 may be electrically connected to the second separation layer L2. The first to third anode electrodes AE1, AE2, and AE3 may be electrically connected to the pixel circuit layer PCL respectively through the second separation layers L2 and/or the first to third reflective electrodes RE1 to RE3.

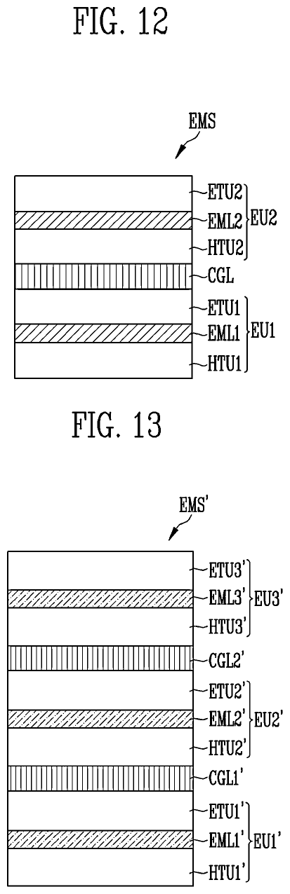

FIG. 12 is a cross-sectional view illustrating an embodiment of the light emitting structure included in any one of the first to third light emitting elements shown in FIG. 7.

Referring to FIG. 12, the light emitting structure EMS may have a tandem structure in which first and second light emitting units EU1 and EU2 are stacked. The light emitting structure EMS may be configured substantially identically in each of the first to third light emitting elements LD1 to LD3 shown in FIG. 7.

Each of the first and second light emitting units EU1 and EU2 may include at least one light emitting layer generating light according to an applied current. The first light emitting unit EU1 may include a first light emitting layer EML1, a first electron transport unit ETU1, and a first hole transport unit HTU1. The first light emitting layer EML1 may be disposed between the first electron transport unit ETU1 and the first hole transport unit HTU1. The second light emitting unit EU2 may include a second light emitting layer EML2, a second electron transport unit ETU2, and a second hole transport unit HTU2. The second light emitting layer EML2 may be disposed between the second electron transport unit ETU2 and the second hole transport unit HTU2.

Each of the first and second hole transport units HTU1 and HTU2 may include at least one of a hole injection layer and a hole transport layer. Each of the first and second hole transport units HTU1 and HTU2 may further include a hole buffer layer, an electron blocking layer, and the like, if necessary. The first and second hole transport units HTU1 and HTU2 may have the same configuration or have different configurations.

Each of the first and second electron transport units ETU1 and ETU2 may include at least one of an electron injection layer and an electron transport layer. Each of the first and second electron transport units ETU1 and ETU2 may further include an electron buffer layer, a hole blocking layer, and the like, if necessary. The first and second electron transport units ETU1 and ETU2 may have the same configuration or have different configurations.

A connection layer, which may be provided in the form of a charge generation layer CGL, may be disposed between the first light emitting unit EU1 and the second light emitting unit EU2 to connect the first light emitting unit EU1 and the second light emitting unit EU2 to each other. In some embodiments, the charge generation layer CGL may have a stacked structure of a p-dopant layer and an n-dopant layer. For example, the p-dopant layer may include a p-type dopant such as HAT-CN, TCNQ or NDP-9, and the n-dopant layer may include an alkali metal, an alkali earth metal, a lanthanide-based metal, or any combination thereof. However, embodiments of the present disclosure are not limited thereto.

In some embodiments, the first light emitting layer EML1 and the second light emitting layer EML2 may generate lights of different colors. Lights that are respectively emitted from the first light emitting layer EML1 and the second light emitting layer EML2 may be mixed together and viewed as white light. For example, the first light emitting layer EML1 may generate light of a blue color, and the second light emitting layer EML2 may generate light of a yellow color. In some embodiments, the second light emitting layer EML2 may include a structure in which a first sub-light emitting layer configured to generate light of a red color and a second sub-light emitting layer configured to generate light of a green color are stacked. The light of the red color and the light of the green color may be mixed together to provide the light of the yellow color. An intermediate layer configured to perform a function of transporting holes and/or a function of blocking transportation of electrodes may be further disposed between the first and second sub-light emitting layers.

In other embodiments, the first light emitting layer EML1 and the second light emitting layer EML2 may generate light of the same color.

The light emitting structure EMS may be formed through a process such as vacuum deposition or inkjet printing, but embodiments of the present disclosure are not limited thereto.

FIG. 13 is a cross-sectional view illustrating another embodiment of the light emitting structure included in the one of the first to third light emitting elements shown in FIG. 7.

Referring to FIG. 13, a light emitting structure EMS′ may include a tandem structure in which first to third light emitting units EU1′ to EU3′ are stacked. The light emitting structure EMS′ may be configured substantially identically in each of the first to third light emitting elements LD1 to LD3 shown in FIG. 7.

Each of the first to third light emitting units EU1′ to EU3′ may include a light emitting layer generating light according to an applied current. The first light emitting unit EU1′ may include a first light emitting layer EML1′, a first electron transport unit ETU1′ and a first hole transport unit HTU1′. The first light emitting layer EML1′ may be disposed between the first electron transport unit ETU1′ and the first hole transport unit HTU1′. The second light emitting unit EU2′ may include a second light emitting layer EML2′, a second electron transport unit ETU2′, and a second hole transport unit HTU2′. The second light emitting layer EML2′ may be disposed between the second electron transport unit ETU2′ and the second hole transport unit HTU2′. The third light emitting unit EU3′ may include a third light emitting layer EML3′, a third electron transport unit ETU3′, and a third hole transport unit HTU3′. The third light emitting layer EML3′ may be disposed between the third electron transport unit ETU3′ and the third hole transport unit HTU3′.

Each of the first to third hole transport units HTU1′ to HTU3′ may include at least one of a hole injection layer and a hole transport layer, and further include a hole buffer layer, and an electron blocking layer, and the like, if necessary. The first to third hole transport units HTU1′ to HTU3′ may have the same configuration or have different configurations.

Each of the first to third electron transport units ETU1′ to ETU3′ may include at least one of an electron injection layer and an electron transport layer, and further include an electron buffer layer, a hole blocking layer, and the like, if necessary. The first to third electron transport units ETU1′ to ETU3′ may have the same configuration or have different configurations.

A first charge generation layer CGL1′ may be disposed between the first light emitting unit EU1′ and the second light emitting unit EU2′. A second charge generation layer CGL2′ may be disposed between the second light emitting unit EU2′ and the third light emitting unit EU3′.

In some embodiments, the first to third light emitting layers EML1′ to EML3′ may generate lights of different colors. Lights respectively emitted from the first to third light emitting layers EML1′ to EML3′ may be mixed together, to be viewed as white light. For example, the first light emitting layer EML1′ may generate light of a blue color, the second light emitting layer EML2′ may generate light of a green color, and the third light emitting layer EML3′ may generate light of a red color.

In other embodiments, light emitting layers of at least two of the first to third light emitting layers EML1′ to EML3′ may generate light of the same color.

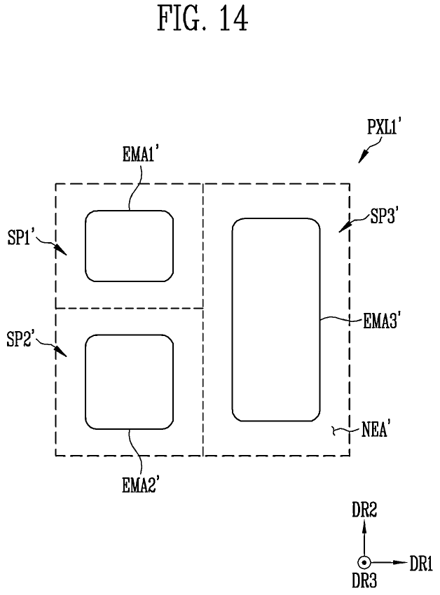

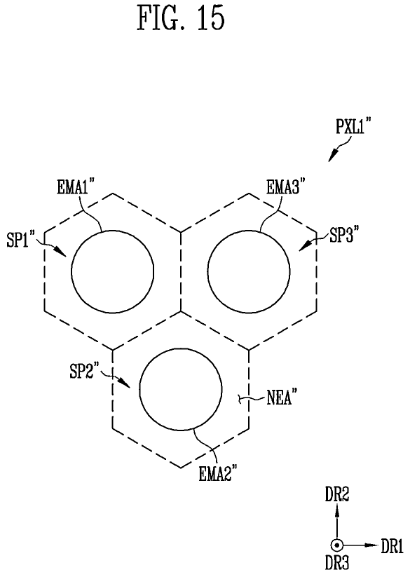

FIG. 14 is a plan view illustrating another embodiment of the one of the pixels shown in FIG. 5.

Referring to FIG. 14, a first pixel PXL1′ may include first to third sub-pixels SP1′ to SP3′.

The first sub-pixel SP1′ may include a first emission area EMA1′ and a non-emission area NEA′ at the periphery of the first emission area EMA1′. The second sub-pixel SP2′ may include a second emission area EMA2′ and the non-emission area NEA′ at the periphery of the second emission area EMA2′. The third sub-pixel SP3′ may include a third emission area EMA3′ and the non-emission area NEA′ at the periphery of the third emission area EMA3′.

The first sub-pixel SP1′ and the second sub-pixel SP2′ may be arranged in the second direction DR2. The third sub-pixel SP3′ may be disposed in the first direction DR1 with respect to each of the first and second sub-pixels SP1′ and SP2′.

The second sub-pixel SP2′ may have an area greater than an area of the first sub-pixel SP1′, and the third sub-pixel SP3′ may have an area greater than the area of the second sub-pixel SP2′.

Accordingly, the second emission area EMA2′ may have an area greater than an area of the first emission area EMA1′, and the third emission area EMA3′ may have an area greater than the area of the second emission area EMA2′. However, embodiments of the present disclosure are not limited thereto. For example, the first and second sub-pixels SP1′ and SP2′ may substantially have the same area, and the third sub-pixel SP3′ may have an area greater than the area of each of the first and second sub-pixels SP1′ and SP2′. As such, the areas of the first to third sub-pixels SP1′ to SP3′ may be variously modified in some embodiments.

FIG. 15 is a plan view illustrating still another embodiment of the one of the pixels shown in FIG. 5.

Referring to FIG. 15, a first sub-pixel SP1″ may include a first emission area EMA1″ and a non-emission area NEA″ at the periphery of the first emission area EMA1″. A second sub-pixel SP2″ may include a second emission area EMA2″ and the non-emission area NEA″ at the periphery of the second emission area EMA2″. A third sub-pixel SP3″ may include a third emission area EMA3″ and the non-emission area NEA″ at the periphery of the third emission area EMA3″.

The first to third sub-pixels SP1″ to SP3″ may have polygonal shapes when viewed in the third direction DR3. For example, the shapes of the first to third sub-pixels SP1″ to SP3″ may be hexagonal shapes as shown in FIG. 11.

The first to third emission areas EMA1″ to EMA3″ may have circular shapes when viewed in the third direction DR3. However, embodiments of the present disclosure are not limited thereto. For example, each of the first to third emission areas EMA1″ to EMA3″ may have a polygonal shape.

The first and third sub-pixels SP1″ and SP3″ may be arranged in the first direction DR1. The second sub-pixel SP2″ may be disposed in a direction (or diagonal direction) inclined by an acute angle, based on the second direction DR2, with respect to the first sub-pixel SP1″.

The arrangements of the sub-pixels, which are shown in FIGS. 6, 14, and 15, are merely illustrative, and embodiments of the present disclosure are not limited thereto. Each pixel may include two or more sub-pixels, and the sub-pixels may be arranged in various manners. Each of the sub-pixels may have various shapes, and an emission area EMA of the sub-pixel may have various shapes.

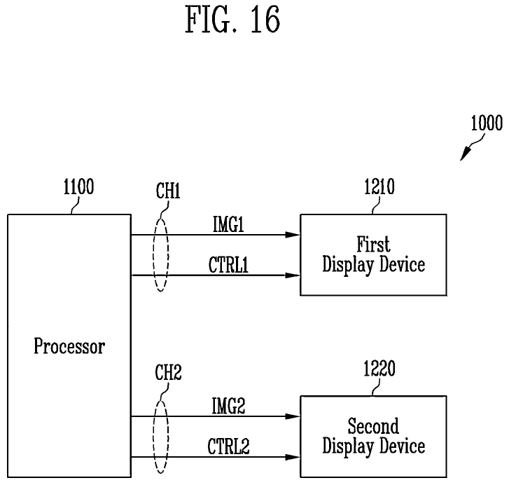

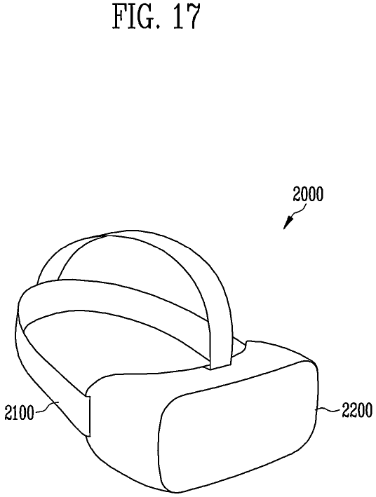

FIG. 16 is a block diagram illustrating an embodiment of a display system.

Referring to FIG. 16, a display system 1000 may include a processor 1100 and one or more display devices 1210 and 1220.

The processor 1100 may perform various tasks and various calculations. In some embodiments, the processor 1100 may include an Application Processor (AP), a Graphics Processing Unit (GPU), a microprocessor, a Central Processing Unit (CPU), and the like. The processor 1100 may be connected to other components of the display system 1000 through a bus system to control the components of the display system 1000.

FIG. 16 illustrates that the display system 1000 includes first and second display devices 1210 and 1220. The processor 1100 may be connected to the first display device 1210 through a first channel CH1, and be connected to the second display device 1220 through a second channel CH2.

Through the first channel CH1, the processor 1210 may transmit first image data IMG1 and a first control signal CTRL1 to the first display device 1210. The first display device 1210 may display an image, based on the first image data IMG1 and the first control signal CTRL1. The first display device 1210 may be configured identically to the display device 100 described with reference to FIG. 1. The first image data IMG1 and the first control signal CTRL1 may be respectively provided as the input image data IMG and the control signal CTRL, which are shown in FIG. 1.

Through the second channel CH2, the processor 1100 may transmit second image data IMG2 and a second control signal CTRL2 to the second display device 1220. The second display device 1220 may display an image, based on the second image data IMG2 and the second control signal CTRL2. The second display device 1220 may be configured identically to the display device 100 described with reference to FIG. 1. The second image data IMG2 and the second control signal CTRL2 may be respectively provided as the image data IMG and the control signal CTRL, which are shown in FIG. 1.

The display system 1000 may include a computing system for providing an image display function, such as a portable computer, a mobile phone, a smartphone, a tablet personal computer (PC), a smart watch, a watch phone, a portable multimedia player (PMP), a navigation system, or an ultra mobile computer (UMPC). The display system 1000 may include at least one of a head mounted display (HMD) device, a virtual reality (VR) device, a mixed reality (MR) device, and an augmented reality (AR) device.

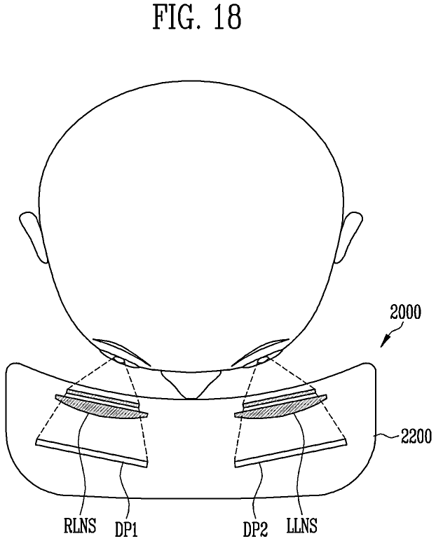

FIG. 17 is a perspective view illustrating an application example of the display system shown in FIG. 16.

Referring to FIG. 17, the display system 1000 shown in FIG. 16 may be applied to a head mounted display device 2000. The head mounted display device 2000 may be a wearable electronic device which can be worn on a head of a user.

The head mounted display device 2000 may include a head mounting band 2100 and a display device accommodating case 2200. The head mounting band 2100 may be connected to the display device accommodating case 2200. The head mounting band 2100 may include a horizontal band and/or a vertical band, used to fix the head mounted display device 2000 to the head of the user. The horizontal band may be configured to surround a side portion of the head of the user, and the vertical band may be configured to surround an upper portion of the head of the user. However, embodiments of the present disclosure are not limited thereto. For example, the head mounting band 2100 may be implemented in the form of a glasses frame, a helmet or the like.

The display device accommodating case 2200 may accommodate the first and second display devices 1210 and 1220 shown in FIG. 16. The display device accommodating case 2200 may further accommodate the processor 1100 shown in FIG. 16.

FIG. 18 is a view illustrating the head-mounted display device shown in FIG. 17, which is worn by a user.

Referring to FIG. 18, a first display panel DP1 of the first display device 1210 and a second display panel DP2 of the second display device 1220 may be disposed in the head mounted display device 2000. The head mounted display device 2000 may further include one or more lenses LLNS and RLNS.

In the display device accommodating case 2200, a right-eye lens RLNS may be disposed between the first display panel DP1 and a right eye of the user. In the display device accommodating case 2200, a left-eye lens LLNS may be disposed between the second display panel DP2 and a left eye of the user.

An image output from the first display panel DP1 may be viewed by the right eye of the user through the right-eye lens RLNS. The right-eye lens RLNS may refract light emitted from the first display panel DP1 to face the right eye of the user. The right-eye lens RLNS may perform an optical function for adjusting a viewing distance between the first display panel DP1 and the right eye of the user.

An image output from the second display panel DP2 may be viewed by the left eye of the user through the left-eye lens LLNS. The left-eye lens LLNS may refract light emitted from the second display panel DP2 to face the left eye of the user. The left-eye lens LLNS may perform an optical function for adjusting a viewing distance between the second display panel DP2 and the left eye of the user.

In some embodiments, each of the right-eye lens RLNS and the left-eye lens LLNS may include an optical lens having a pancake-shaped section. In some embodiments, each of the right-eye lens RLNS and the left-eye lens LLNS may include a multi-channel lens including sub-areas having different optical characteristics. Each display panel may output images respectively corresponding to the sub-areas of the multi-channel lens, and the output images may be viewed by the user while respectively passing through corresponding sub-areas.

Continuously, a method of manufacturing the display device in accordance with the above-described embodiment will be described.

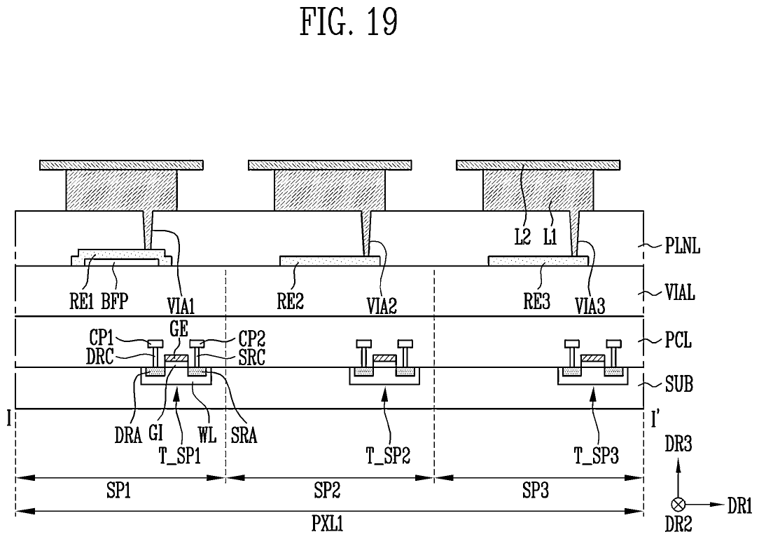

FIGS. 19 to 26 are cross-sectional views illustrating process steps of a method of manufacturing a display device in accordance with an embodiment of the present disclosure. FIGS. 19 to 26 are cross-sectional views illustrating a method of manufacturing the display device shown in FIGS. 7 to 9. For convenience of description, configurations shown in FIGS. 19 to 26 are briefly illustrated, and detailed reference numerals are omitted.

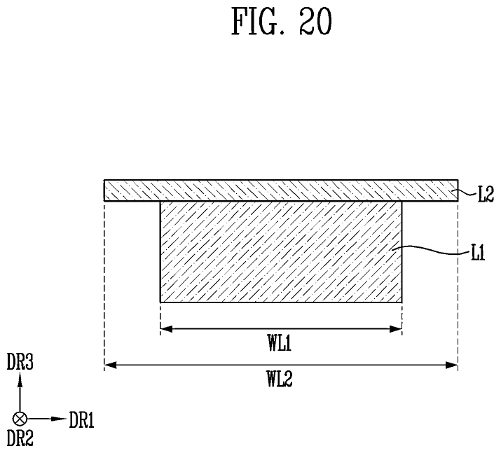

Referring to FIGS. 19 and 20, a first separation layer L1 and a second separation layer L2 are formed on the substrate SUB. The first separation layer L1 and the second separation layer L2 may be formed in each of the first to third emission areas EMA1 to EMA3 (see FIG. 6) of the substrate SUB.

The first separation layer L1 may be formed on a planarization layer PLNL. The first separation layer L1 may be formed directly on the planarization layer PLNL. First separation layers L1 of first to third sub-pixels SP1 to SP3 may be electrically connected to first to third reflective electrodes RE1 to RE3 disposed thereunder through vias extending through the planarization layer PLNL, respectively. The first separation layer L1 of the first sub-pixel SP1 may be electrically connected to the first reflective electrode RE1 through a first via VIA1 extending through the planarization layer PLNL. The first separation layer L1 of the second sub-pixel SP2 may be electrically connected to the second reflective electrode RE2 through a second via VIA2 extending through the planarization layer PLNL. The first separation layer L1 of the third sub-pixel SP3 may be electrically connected to the third reflective electrode RE3 through a third via VIA3 extending through the planarization layer PLNL. The first separation layers L1 of the first to third sub-pixels SP1 to SP3 may be electrically connected to a pixel circuit layer PCL respectively through the first to third reflective electrodes RE1 to RE3. In an embodiment, the first separation layer L1 may be formed of a conductive material. In an example, the first separation layer L1 may include at least one of aluminum (Al), silver (Ag), magnesium (Mg), platinum (Pt), palladium (Pd), gold (Au), nickel (Ni), neodymium (Nd), iridium (Ir), chromium (Cr), and alloys of two or more materials selected therefrom, but embodiments of the present disclosure are not limited thereto.

The second separation layer L2 may be formed on the first separation layer L1. The second separation layer L2 may be formed directly on the first separation layer L1. The second separation layer L2 may be formed of a conductive material. In an example, the second separation layer L2 may include at least one of aluminum (Al), silver (Ag), magnesium (Mg), platinum (Pt), palladium (Pd), gold (Au), nickel (Ni), neodymium (Nd), iridium (Ir), chromium (Cr), and alloys of two or more materials selected therefrom, but embodiments of the present disclosure are not limited thereto.

A width WL1 of the first separation layer L1 in the first direction DR1 may be smaller than a width WL2 of the second separation layer L2 in the first direction DR1. The second separation layer L2 may cover with the entire top surface of the first separation layer L1. One side of the second separation layer L2 may extend beyond the edge of one side of the first separation layer L1. The other side of the second separation layer L2 may extend beyond the edge of the other side of the first separation layer L1.

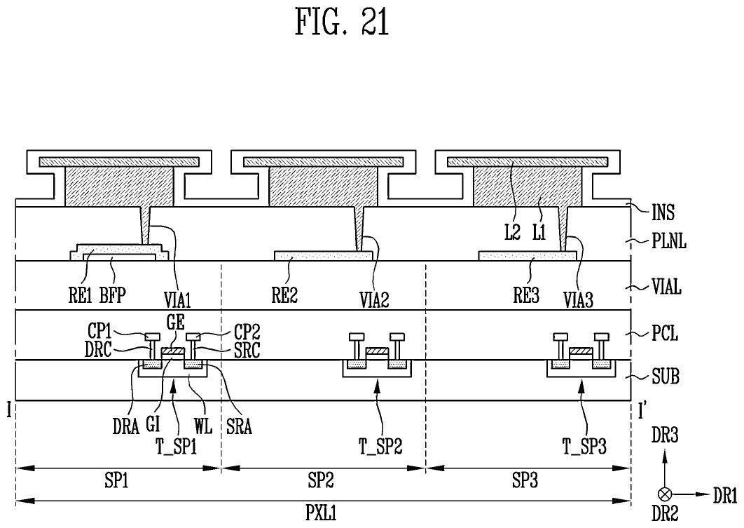

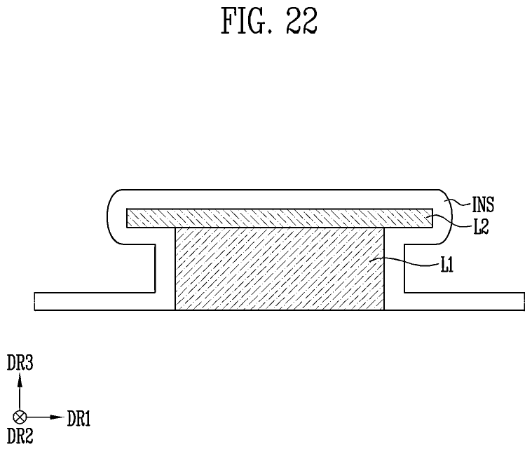

Referring to FIGS. 21 and 22, subsequently, an insulating layer INS is formed over the first separation layer L1 and the second separation layer L2. The insulating layer INS may cover the first separation layer L1 and the second separation layer L2. The insulating layer INS may include various kinds of inorganic insulating materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ), but the present disclosure is not necessarily limited thereto.

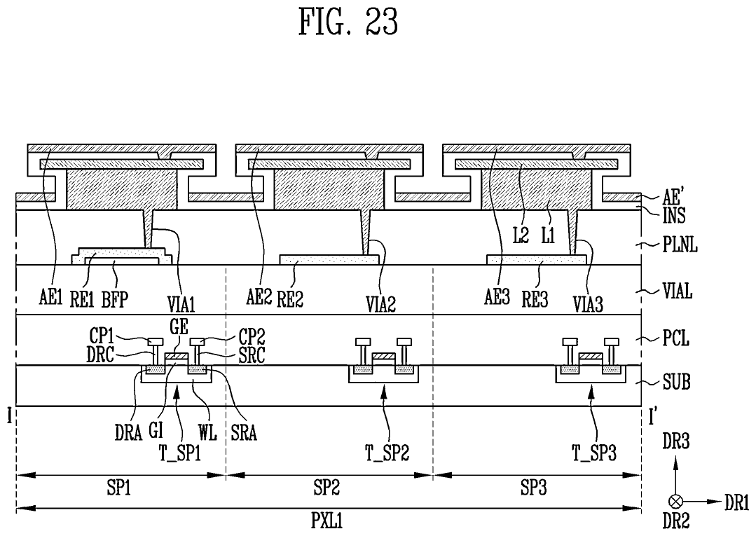

Referring to FIGS. 23 to 25, subsequently, a first electrode AE and AE′ is formed on the insulating layer INS. The first electrode AE and AE′ may be entirely deposited on the insulating layer INS. A first area, i.e., an anode electrode AE of the first electrode and a second area, i.e., a conductive pattern AE′ of the first electrode may be separated from each other by a T-shaped structure formed by the first separation layer L1 and the second separation layer L2. In an example, the anode electrode AE as the first area of the first electrode may be formed on the first separation layer L1 and the second separation layer L2, and the conductive pattern AE′ as the second area separated from the first area of the first electrode may be formed between the first separation layers L1 of the first to third sub-pixels SP1 to SP3 or between the second separation layers L2 of the first to third sub-pixels SP1 to SP3. A separate etching process for separating first to third anode electrodes AE1, AE2, and AE3 from each other is unnecessary, and an ultra high definition display device can be implemented.

Each of the first to third anode electrodes AE1, AE2, and AE3 may be electrically connected to the second separation layer L2 through a contact hole extending through the insulating layer INS. The first anode electrode AE1 may be electrically connected to the second separation layer L2 of the first sub-pixel SP1 through a contact hole extending through the insulating layer INS. The second anode electrode AE2 may be electrically connected to the second separation layer L2 of the second sub-pixel SP2 through a contact hole extending through the insulating layer INS. The third anode electrode AE3 may be electrically connected to the second separation layer L2 of the third sub-pixel SP3 through a contact hole extending through the insulating layer INS.

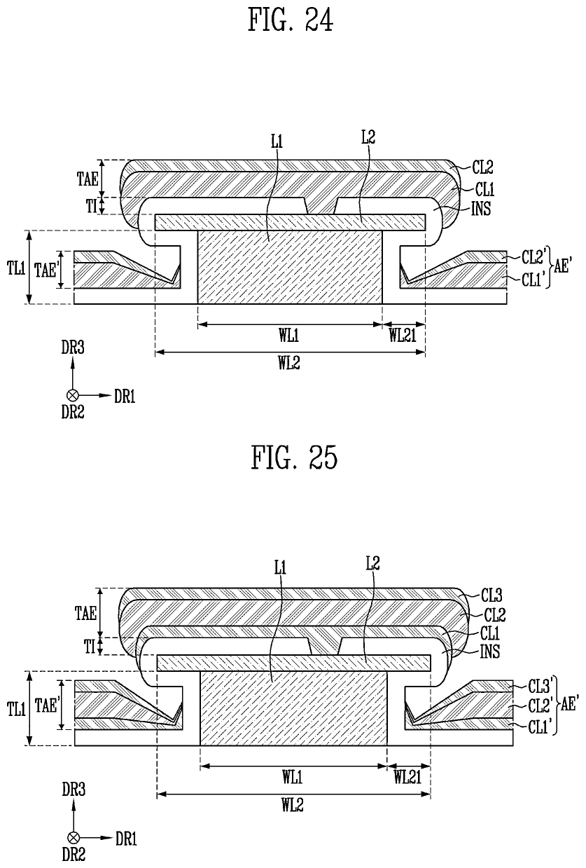

Referring to FIG. 24, a thickness TAE of the anode electrode AE in the third direction DR3 may be equal to a thickness TAE′ of the conductive pattern AE′ in the third direction DR3. In some embodiments, the thickness of the conductive pattern AE′ may become thinner as it gets closer to the first separation layer L1 and the second separation layer L2, and become thick again to contact the insulating layer INS. However, the change in the thickness of the conductive pattern AE′ is not necessarily limited to this embodiment, and may be changed.

A length WL21 by which the second separation layer L2 extends beyond the edge of the first separation layer L1 in the first direction DR1 may be greater than the thickness TAE of the anode electrode AE in the third direction DR3 or the thickness TAE′ of the conductive pattern AE′ in the third direction DR3. A thickness TL1 of the first separation layer L1 in the third direction DR3 may be greater than a sum of a thickness TI of the insulating layer INS and the thickness TAE of the anode electrode AE in the third direction DR3. The thickness TL1 of the first separation layer L1 in the third direction DR3 may be greater than a sum of the thickness TI of the insulating layer INS in the third direction DR3 and the thickness TAE′ of the conductive pattern AE′ in the third direction DR3.

The anode electrode AE and the conductive pattern AE′ may include two or more conductive layers. For example, the anode electrode AE may include a first electrode layer CL1 and a second electrode layer CL2 disposed on the first electrode layer CL1. The conductive pattern AE′ may include a first electrode layer CL1′ and a second electrode layer CL2′ disposed on the first electrode layer CL1′. Tthe first electrode layers CL1 and CL1′ may be disposed between the insulating layer INS and the second electrode layers CL2 and CL2′, respectively. The second electrode layers CL2 and CL2′ may be disposed directly on the first electrode layers CL1 and CL1′, respectively.

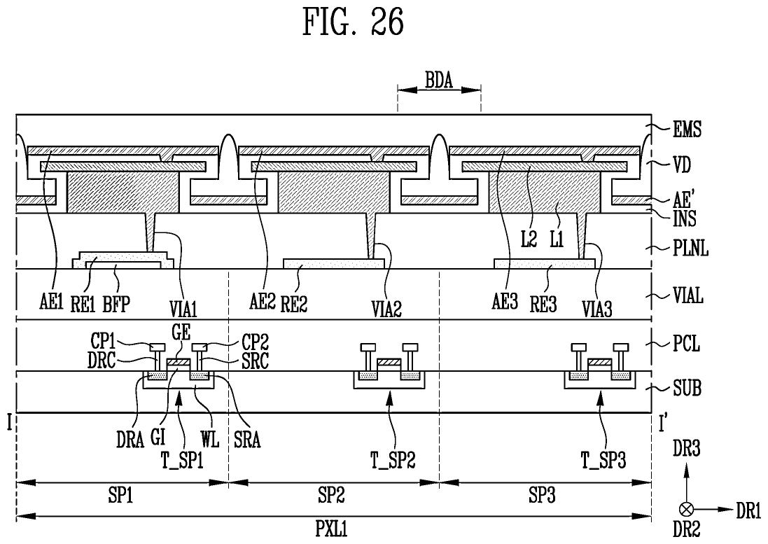

Referring to FIG. 25, the anode electrode AE may include a first electrode layer CL1, a second electrode CL2 disposed on the first electrode layer CL1, and a third electrode layer CL3 disposed on the second electrode layer CL2. The conductive pattern AE′ may include a first electrode layer CL1′, a second electrode layer CL2′ disposed on the first electrode layer CL1′, and a third electrode layer CL3′ disposed on the second electrode layer CL2′. The first electrode layers CL1 and CL1′ may be disposed between the insulating layer INS and the second electrode layers CL2 and CL2′, respectively. The second electrode layer CL2 may be disposed between the first electrode layer CL1 and the third electrode layer CL3, and the second electrode layer CL2′ may be disposed between the first electrode layer CL1′ and the third electrode layer CL3′. The second electrode layers CL2 and CL2′ may be disposed directly on the first electrode layers CL1 and CL1′, respectively. The third electrode layers CL3 and CL3′ may be disposed directly on the second electrode layers CL2 and CL2′, respectively.

Referring to FIG. 26, subsequently, a light emitting structure EMS may be formed on the anode electrode AE and the conductive pattern AE′. The light emitting structure EMS may be formed continuously across the first to third sub-pixels SP1 to SP3. Some or all of a plurality of layers included in the light emitting structure EMS may be at least partially separated or curved on the conductive pattern AE′. Some or all of the plurality of layers included in the light emitting structure EMS may be at least partially separated or curved in a boundary area BDA by a void VD. For example, at least one charge generation layer included in the light emitting structure EMS may be separated in the boundary area BDA by the void VD. Due to this separation, during operation of the display panel DP, a current leaked from each of the first to third sub-pixels SP1 to SP3 to a sub-pixel adjacent to each of the first to third sub-pixels SP1 to SP3 through the layers included in the light emitting structure EMS can decrease. Thus, first to third light emitting elements LD1 to LD3 can operate with relatively high reliability, as described above.

Subsequently, a cathode electrode CE, an encapsulation layer TFE, an optical functional layer OFL, an overcoat layer OC, a cover window CW, and the like are sequentially formed on the light emitting structure EMS, thereby completing the display device shown in FIGS. 7 to 9.

In accordance with the present disclosure, a first electrode (e.g., anode electrode AE) can be separated without any separate etching process, and an ultra high definition display device can be implemented. In addition, a portion or the whole of a light emitting structure can be separated in a boundary area between sub-pixels, minimizing a current leaked to adjacent sub-pixels.

Although the disclosure has been described according to the herein-described embodiments, the herein-described embodiments are for describing the disclosure and not for limiting the scope of the disclosure. Those of ordinary skill in the art to which the disclosure pertains will understand that one or more suitable modifications are possible within the scope of the technical spirit of the disclosure.

The scope of the disclosure is not limited to the details described in the detailed description of the specification, but should also be defined by the claims, and equivalents thereof. It is to be construed that all changes or modifications derived from the meaning and scope of the claims and equivalent concepts thereof are included in the scope of the disclosure.

What is claimed is:

1. A display device comprising:
a first separation layer disposed in an emission area of a substrate;
a second separation layer disposed on the first separation layer;
an insulating layer disposed on the second separation layer;
a first electrode disposed on the insulating layer;
a light emitting structure disposed on the first electrode; and
a second electrode disposed on the light emitting structure,
wherein the first electrode includes a first area on the second separation layer and a second area electrically separated from the first area.

2. The display device of claim 1, wherein a width of the second separation layer in a first direction is greater than a width of the first separation layer in the first direction.

3. The display device of claim 1, wherein a width by which the second separation layer extends beyond the first separation layer is greater than a thickness of the first electrode.

4. The display device of claim 1, wherein at least part of the light emitting structure is discontinuous on the second area of the first electrode.

5. The display device of claim 1, wherein the first electrode includes a first electrode layer disposed on the insulating layer and a second electrode layer disposed on the first electrode layer.

6. The display device of claim 5, wherein the first electrode further includes a third electrode layer disposed on the second electrode layer.

7. The display device of claim 6, wherein the first electrode layer and the third electrode layer include the same material.

8. The display device of claim 1, wherein a thickness of the first separation layer is greater than a sum of a thickness of the insulating layer and a thickness of the first electrode.

9. The display device of claim 1, wherein the insulating layer covers the first separation layer and the second separation layer.

10. The display device of claim 1, wherein the first area of the first electrode is electrically connected to the second separation layer through a contact hole that extends through the insulating layer.

11. The display device of claim 1, wherein the substrate includes a first sub-pixel and a second sub-pixel that are adjacently positioned, and
wherein the second area of the first electrode is disposed in a boundary area between the first sub-pixel and the second sub-pixel.

12. The display device of claim 11, wherein the light emitting structure of the first sub-pixel and the light emitting structure of the second sub-pixel are separated from each other on the second area of the first electrode.

13. The display device of claim 11, wherein the second electrode of the first sub-pixel and the second electrode of the second sub-pixel are connected to each other on the second area of the first electrode.

14. The display device of claim 1, wherein the first separation layer and the second separation layer include a conductive material.

15. A display device comprising:
a first separation layer disposed in an emission area of a substrate;
a second separation layer disposed on the first separation layer;
an anode electrode disposed on the second layer;
a conductive pattern disposed in the same layer as the first separation layer, the conductive pattern being electrically separated from the anode electrode;
a light emitting structure disposed on the anode electrode and the conductive pattern; and
a cathode electrode disposed on the light emitting structure,
wherein the anode electrode and the conductive pattern include the same material.

16. The display device of claim 15, further comprising a circuit layer disposed between the substrate and the anode electrode.

17. The display device of claim 16, wherein the second separation layer is electrically connected to the circuit layer through a contact hole that extends through the first separation layer.

18. The display device of claim 16, wherein the anode electrode is electrically connected to the circuit layer through a contact hole that extends through the second layer and the first separation layer.

19. The display device of claim 15, wherein the first separation layer includes an insulating material, and the second separation layer includes a conductive material.

20. The display device of claim 15, wherein the first separation layer and the second separation layer include an insulating material.
